(19) United States
(12) Patent Application Publication
(10) Pub. No.: US 2020/0225580 A1
(43) Pub. Date: Jul. 16, 2020

(54) CURABLE COMPOSITION, CURED FILM, SOLID-STATE IMAGING DEVICE, AND MANUFACTURING METHOD OF CURED FILM

(71) Applicant: FUJIFILM Corporation, Tokyo (JP)

(72) Inventor: Daisuke HAMADA, Haibara-gun (JP)

(73) Assignee: FUJIFILM Corporation, Tokyo (JP)

(21) Appl. No.: 16/826,454

(22) Filed: Mar. 23, 2020

Related U.S. Application Data
(63) Continuation of application No. PCT/JP2018/034835, filed on Sep. 20, 2018.

(30) Foreign Application Priority Data
Sep. 26, 2017 (JP) 2017-184479

(51) Int. Cl. G03F 7/031; C08F 20/30; G03F 7/029; G03F 7/16; G03F 7/20; G03F 7/32; G02B 5/00

(52) U.S. Cl. CPC G03F 7/031; C08F 20/30; G03F 7/0295; G02B 5/003; G03F 7/168; G03F 7/2006; G03F 7/322; G03F 7/162

(57) ABSTRACT

The present invention provides a curable composition, which makes it possible to form a curable composition layer having excellent temporal stability against delay, a cured film, a solid-state imaging device, and a manufacturing method of a cured film. The curable composition according to an embodiment of the present invention contains carbon black and a polymerizable compound, in which the polymerizable compound contains a first polymerizable compound having a ring-opened structure of ε-caprolactone and a second polymerizable compound having a hydroxyl group.

### CROSS-REFERENCE TO RELATED APPLICATIONS

This application is a Continuation of PCT International Application No. PCT/JP2018/034835 filed on Sep. 20, 2018, which claims priority under 35 U.S.C. § 119(a) to Japanese Patent Application No. 2017-184479 filed on Sep. 26, 2017. The above application is hereby expressly incorporated by reference, in its entirety, into the present application.

### BACKGROUND OF THE INVENTION

### 1. Field of the Invention

The present invention relates to a curable composition, a cured film, a solid-state imaging device, and a manufacturing method of a cured film.

### 2. Description of the Related Art

Conventionally, examinations have been carried out regarding the use of a cured film, which is formed using a curable composition containing carbon black, for various purposes. For example, in order to prevent the occurrence of noise, improve image quality, and the like, examinations have been carried out regarding the use of the cured film in a light blocking film to be disposed in a solid-state imaging device.

As the curable composition containing carbon black, a photosensitive resin composition is disclosed which contains carbon black and a dipentaerythritol polyacrylate compound.

### SUMMARY OF THE INVENTION

In a case where a cured film is formed using a curable composition, generally, after a curable composition layer is formed, a curing treatment such as an exposure treatment is performed. Depending on the manufacturing procedure, in some cases, it takes a long time until the curable composition layer is subjected to the curing treatment after the layer is formed. That is, sometimes a delay time is prolonged.

As a result of examining the curable composition described in JP2005-189720A, the inventors of the present invention have found that in a case where a curable composition layer is formed using a curable composition and then left to stand for a long period of time, defects occur in the curable composition layer. Hereinafter, the properties that make it difficult for defects to occur in a curable composition layer in a case where the curable composition layer is left to stand after being formed will be described as having excellent temporal stability against delay.

An object of the present invention is to provide a curable composition which makes it possible to form a curable composition layer having excellent temporal stability against delay.

Another object of the present invention is to provide a cured film, a solid-state imaging device, and a manufacturing method of a cured film.

In order to achieve the above objects, the inventors of the present invention conducted an intensive study. As a result, the inventors have found that the objects can be achieved by the following constitution.

(1) A curable composition containing carbon black and a polymerizable compound, in which the polymerizable compound contains a first polymerizable compound having a ring-opened structure of s-caprolactone and a second polymerizable compound having a hydroxyl group.

(2) The curable composition described in (1), in which the polymerizable compound further contains a third polymerizable compound which is a compound different from the first polymerizable compound and the second polymerizable compound and has a plurality of polymerizable groups.

(3) The curable composition described in (2), in which the third polymerizable compound contains a polymerizable compound which is a compound different from the first polymerizable compound and the second polymerizable compound and has a plurality of polymerizable groups, in which a ratio obtained by dividing the number of the polymerizable groups by a molecular weight of the polymerizable compound contained in the third polymerizable compound is equal to or higher than 0.0100 and less than 0.0120.

(4) The curable composition described in any one of (1) to (3), in which at least 4 or more kinds of compounds are contained as the polymerizable compound.

(5) The curable composition described in any one of (1) to (4), in which at least 3 or more kinds of compounds having different numbers of polymerizable groups are contained as the polymerizable compound.

(6) The curable composition described in any one of (1) to (5), in which at least 4 or more kinds of compounds having different numbers of polymerizable groups are contained as the polymerizable compound.

(7) The curable composition described in any one of (1) to (6), in which the first polymerizable compound is a compound represented by Formula (Z-1) which will be described later.

(8) The curable composition described in (7), in which two R's among six R's are a group represented by Formula (Z-2) which will be described later, and other R's are a group represented by Formula (Z-3) which will be described later.

(9) The curable composition described in any one of (1) to (8), in which the second polymerizable compound is selected from the group consisting of a compound represented by Formula (Z-4) which will be described later and a compound represented by Formula (Z-5) which will be described later.

(10) The curable composition described in any one of (1) to (9), in which the polymerizable compound contains a compound represented by Formula (Z-1) which will be described later, a compound represented by Formula (Z-5) which will be described later, a compound represented by Formula (Z-6) which will be described later, and a compound represented by Formula (Z-7) which will be described later.

(11) The curable composition described in any one of (1) to (10) further containing an α-aminoketone-based polymerization initiator.

(12) The curable composition described in any one of (1) to (11) further containing an oxime ester-based polymerization initiator.

(13) The curable composition described in any one of (1) to (12) further containing an alkali-soluble resin which has a curable group and a cardo structure.

(14) The curable composition described in any one of (1) to (13) further containing a solvent having a boiling point equal to or higher than 170° C.

(15) The curable composition described in any one of (1) to (14) further containing titanium black.

(16) A cured film obtained by curing the curable composition described in any one of (1) to (15).

(17) A solid-state imaging device having the cured film described in (16).

(18) A manufacturing method of a cured film, having a step of forming a curable composition layer by using the curable composition described in any one of (1) to (15), a step of exposing the curable composition layer, and a step of developing the exposed curable composition layer by using a developer.

According to the present invention, it is possible to provide a curable composition which makes it possible to form a curable composition layer having excellent temporal stability against delay.

Furthermore, according to the present invention, it is possible to provide a cured film, a solid-state imaging device, and a manufacturing method of a cured film.

### BRIEF DESCRIPTION OF THE DRAWINGS

FIG. 1 is a schematic cross-sectional view showing an example of the constitution of a solid-state imaging device.

FIG. 2 is an enlarged schematic cross-sectional view showing an imaging portion in FIG. 1.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

In the present specification, a range of numerical values described using “to” means a range including the numerical values listed before and after “to” as a lower limit and an upper limit respectively.

In the present specification, regarding the description of a group (atomic group), in a case where whether the group is substituted or unsubstituted is not described, the group includes a group which does not have a substituent and a group which has a substituent. For example, “alkyl group” includes not only an alkyl group which does not have a substituent (unsubstituted alkyl group) but also an alkyl group which has a substituent (substituted alkyl group).

Furthermore, in the present specification, “actinic rays” or “radiation” means, for example, far ultraviolet rays, extreme ultraviolet radiation (EUV: extreme ultraviolet), X-rays, electron beams, and the like. In addition, in the present specification, light means actinic rays and radiation. In the present specification, unless otherwise specified, “exposure” includes not only exposure by far ultraviolet rays, X-rays, and EUV, but also lithography by particle beams such as electron beams and ion beams.

In the present specification, “(meth)acrylate” represents acrylate and methacrylate, “(meth)acryl” represents acryl and methacryl, “(meth)acryloyl” represents acryloyl and methacryloyl, “(meth)acrylamide” represents acrylamide and methacrylamide, and “(meth)allyl” represents allyl or methallyl. Furthermore, in the present specification, “tanryotai” in Japanese and “monomer” have the same definition. The monomer is classified into an oligomer and a polymer, and refers to a compound having a weight-average molecular weight equal to or smaller than 2,000. In the present specification, a polymerizable compound refers to a compound containing a polymerizable group, and may be a monomer or a polymer. The polymerizable group refers to a group which takes part in a polymerization reaction.

The curable composition according to an embodiment of the present invention contains carbon black and a polymerizable compound. The polymerizable compound contains a first polymerizable compound having a ring-opened structure of ε-caprolactone and a second polymerizable compound having a hydroxyl group.

Details of the reason why the desired effects are obtained from the curable composition are unclear. Presumably, because the curable composition uses 2 kinds of predetermined polymerizable compounds, the aggregation of carbon black in the curable composition layer may be inhibited, phase separation between the polymerizable compounds may also be inhibited, and accordingly, the desired effects may be obtained.

Hereinafter, each of the components contained in the curable composition will be described.

<Carbon Black>

The curable composition contains carbon black.

Examples of the carbon black include furnace black, thermal black, channel black, lamp black, and acetylene black.

Among these, as the carbon black, furnace black is preferable.

Furthermore, the surface of the carbon black may be treated by known methods.

The shape of the carbon black is not particularly limited, but it is preferable that the carbon black is in the form of particles.

The particle diameter of the carbon black is not particularly limited. However, in view of dispersibility and colorability, the average primary particle diameter of the carbon black is preferably 1 to 200 nm, and more preferably 10 to 100 nm.

The average primary particle diameter of the carbon black can be measured using a Transmission Electron Microscope (TEM). As the transmission electron microscope, for example, a transmission electron microscope HT7700 manufactured by Hitachi High-Technologies Corporation can be used.

For a particle image obtained using a transmission electron microscope, a maximum length (Dmax: maximum length between two points on the contour of the particle image) and a vertical length to maximum length (Dv-max: in a case where the image is interposed between two straight lines parallel to the line of the maximum length, DV-max is a minimum length of a line vertically connecting the two straight lines) are measured, and the value of geometrical mean thereof (Dmax×DV-max)^{1/2} is adopted as a particle diameter. By this method, particle diameters are measured for 100 particles, and the arithmetic mean thereof is calculated so as to determine the average particle diameter. The average particle diameter is adopted as the average primary particle diameter of the carbon black.

One kind of carbon black may be used singly, or two or more kinds of carbon black may be used in combination.

The content of the carbon black in the curable composition with respect to the total solid content of the curable composition is preferably 10% to 80% by mass, more preferably 20% to 60% by mass, and even more preferably 30% to 50% by mass.

The total solid content means the components that can constitute a cured film and does not include a solvent.

The carbon black can be used as a dispersion liquid which is obtained by mixing and dispersing the carbon black together with an appropriate dispersant, solvent, and the like by using a mixing device such as a beads mill, a ball mill, or a rod mill.

Examples of the solvent used for preparing the dispersion liquid include a solvent, which which will be described later as a solvent that the curable composition can contain, alcohols such as 1-propanol, 2-propanol, 1-butanol, 2-butanol, 2-methyl-2-propanol, 1-pentanol, 2-pentanol, 3-pentanol, 3-methyl-butanol, 2-methyl-2-butanol, neopentanol, cyclopentanol, 1-hexanol, and cyclohexanol, and the like.

Among these, propylene glycol methyl ether acetate (PGMEA) is preferable.

One kind of each of these solvents may be used singly, or two or more kinds of these solvents may be used in combination.

The content of the carbon black in the dispersion liquid with respect to the total mass of the dispersion liquid is preferably 1% to 70% by mass, and more preferably 10% to 30% by mass.

<Polymerizable Compound>

The curable composition contains a polymerizable compound.

The polymerizable compound contains a first polymerizable compound having a ring-opened structure of ε-caprolactone (hereinafter, simply referred to as “first polymerizable compound” as well) and a second polymerizable compound having a hydroxyl group (hereinafter, simply referred to as “second polymerizable compound” as well).

(First Polymerizable Compound)

The first polymerizable compound is a polymerizable compound having a ring-opened structure of s-caprolactone.

The ring-opened structure of s-caprolactone is a structure represented by the following Formula (A).

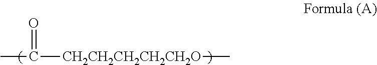

In the first polymerizable compound, two structures represented by Formula (A) may be linked to each other. For example, the first polymerizable compound may have a structure represented by Formula (B).

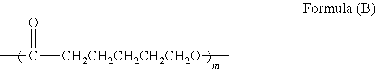

In Formula (B), m represents 1 or 2.

The first polymerizable compound has a polymerizable group. The number of polymerizable groups in the first polymerizable compound is not particularly limited, but is preferably equal to or greater than 1, more preferably equal to or greater than 2, even more preferably equal to or greater than 3, and particularly preferably equal to or greater than 5. The upper limit thereof is not particularly limited. For example, the upper limit thereof is equal to or smaller than 10, and preferably equal to or smaller than 6.

As the polymerizable group, a group containing an ethylenically unsaturated bond is preferable. Examples thereof include a vinyl group, a (meth)allyl group, and a (meth)acryloyl group.

The structure of the first polymerizable compound is not particularly limited as long as the compound has the ring-opened structure of ε-caprolactone. For example, s-caprolactone-modified polyfunctional (meth)acrylate is preferable which is obtained by esterifying a polyhydric alcohol such as trimethylolethane, ditrimethylolethane, trimethylolpropane, ditrimethylolpropane, pentaerythritol, dipentaerythritol, tripentaerythritol, glycerin, diglycerol, or trimethylol melamine, (meth)acrylic acid, and ε-caprolactone. Particularly, a compound represented by Formula (Z-1) is more preferable.

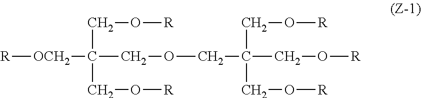

In Formula (Z-1), all of six R's are a group represented by Formula (Z-2). Alternatively, one to five R's among six R's are a group represented by Formula (Z-2), and the others are a group represented by Formula (Z-3).

It is preferable that two to six R's a group represented by Formula (Z-2), and the others are a group represented by Formula (Z-3). It is more preferable that two R's are a group represented by Formula (Z-2), and the others (four R's) are a group represented by Formula (Z-3).

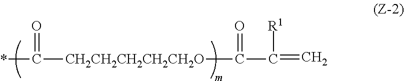

In Formula (Z-2), R¹ represents a hydrogen atom or a methyl group. m represents 1 or 2. * represents a binding position.

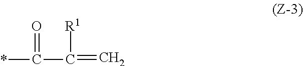

In Formula (Z-3), R¹ represents a hydrogen atom or a methyl group. * represents a binding position.

Examples of the first polymerizable compound include compounds commercially available as a KAYARAD DPCA series from Nippon Kayaku Co., Ltd., such as DPCA-20 (a compound represented by any of Formulae (Z-1) to (Z-3) in which m=1, the number of groups represented by Formula (Z-2)=2, and all of R¹'s represent a hydrogen atom), DPCA-30 (a compound represented by any of Formulae (Z-1) to (Z-3) in which m=1, the number of groups represented by Formula (Z-2)=3, and all of R¹'s represent a hydrogen atom), DPCA-60 (a compound represented by any of Formulae (Z-1) to (Z-3) in which m=1, the number of groups represented by Formula (Z-2)=6, and all of R¹'s represent a hydrogen atom), DPCA-120 (a compound represented by any of Formulae (Z-1) to (Z-3) in which m=2, the number of groups represented by Formula (Z-2)=6, and all of R¹'s represent a hydrogen atom), and the like.

The content of the first polymerizable compound in the curable composition with respect to the total solid content of the curable composition is preferably 0.1% to 30% by mass, more preferably 1% to 25% by mass, and even more preferably 3% to 20% by mass.

One kind of first polymerizable compound may be used singly, or two or more kinds of first polymerizable compounds may be used in combination. In a case where two or more kinds of first polymerizable compounds are used in combination, the total content thereof is preferably within the above range.

(Second Polymerizable Compound)

The second polymerizable compound is a polymerizable compound having a hydroxyl group.

There is no particular limitation on the number of hydroxyl groups that the second polymerizable compound has. However, the number of hydroxyl groups is preferably equal to or greater than 1, preferably 1 to 3, and more preferably 1.

The second polymerizable compound has a polymerizable group. The number of polymerizable groups in the second polymerizable compound is not particularly limited, but is preferably equal to or greater than 1, more preferably equal to or greater than 2, and even more preferably equal to or greater than 3. The upper limit thereof is not particularly limited. For example, the upper limit thereof is equal to or smaller than 10, and preferably equal to or smaller than 6.

As the polymerizable group, a group containing an ethylenically unsaturated bond is preferable. Examples thereof include a vinyl group, a (meth)allyl group, and a (meth)acryloyl group.

As the second polymerizable compound, a compound selected from the group consisting of a compound represented by Formula (Z-4) and a compound represented by Formula (Z-5) is preferable.

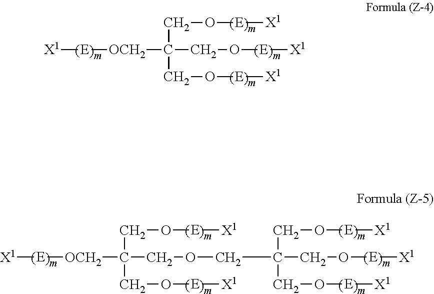

In Formula (Z-4), E each independently represents —((CH₂)_{y}CH₂O)-*1 or —((CH₂)_{y}CH(CH₃)O)-*1, y each independently represents an integer of 0 to 10, and m each independently represents an integer of 0 to 10. One to three X¹'s among four X¹'s represent a (meth)acryloyl group, and the others represent a hydrogen atom. *1 represents a binding position on the X¹ side.

Particularly, in view of further improving the effects of the present invention, an aspect is preferable in which all of four m's represent 0, and an aspect is more preferable in which all of four m's represent 0, three X¹'s among four X¹'s represent a (meth)acryloyl group, and the other (one X¹) represents a hydrogen atom.

That is, a compound represented by Formula (Z-4-1) is more preferable.

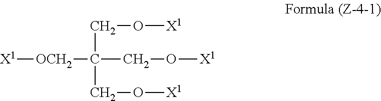

In Formula (Z-4-1), three X¹'s among four X¹'s represent a (meth)acryloyl group, and the other (one X¹) represents a hydrogen atom.

In Formula (Z-5), E each independently represents —((CH₂)_{y}CH₂O)-*1 or —((CH₂)_{y}CH(CH₃)O)-*1, y each independently represents an integer of 0 to 10, and n each independently represents an integer of 0 to 10. One to five X¹'s among six X¹'s represent a (meth)acryloyl group, and the others represent a hydrogen atom. *1 represents a binding position on the X¹ side.

Particularly, in view of further improving the effects of the present invention, an aspect is preferable in which all of six n's represent 0, and an aspect is more preferable in which all of six n's represent 0, five X¹'s among six X¹'s represent a (meth)acryloyl group, and the other (one X¹) represents a hydrogen atom.

That is, a compound represented by Formula (Z-5-1) is more preferable.

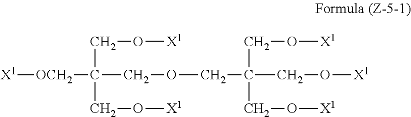

In Formula (Z-5-1), five X¹'s among six X¹'s represent a (meth)acryloyl group, and the other (one X¹) represents a hydrogen atom.

The content of the second polymerizable compound in the curable composition with respect to the total solid content of the curable composition is preferably 0.1% to 30% by mass, more preferably 1% to 25% by mass, and even more preferably 3% to 20% by mass.

One kind of second polymerizable compound may be used singly, or two or more kinds of second polymerizable compounds may be used in combination. In a case where two or more kinds of second polymerizable compounds are used in combination, the total content thereof is preferably within the above range.

(Others)

The curable composition may contain other polymerizable compounds in addition to the first polymerizable compound and the second polymerizable compound described above.

For example, the polymerizable compound may contain a third polymerizable compound which is a compound different from the first polymerizable compound and the second polymerizable compound and has a plurality of polymerizable groups.

In a case where the curable composition contains the third polymerizable compound (particularly, a polymerizable compound in which a ratio obtained by dividing the number of the polymerizable groups by the molecular weight of the compound is equal to or higher than 0.0100 and less than 0.0120 as will be described later), the evaluation result of temporal stability against delay and the evaluation result of post-development lenticulation are further improved.

The third polymerizable compound is a compound different from the first polymerizable compound and the second polymerizable compound. That is, the third polymerizable compound is a compound having none of the ring-opened structure of ε-caprolactone and the hydroxyl group.

As the third polymerizable compound, in view of further improving the evaluation result of post-development lenticulation which will be described later, a compound selected from the group consisting of a compound represented by Formula (Z-6) and a compound represented by Formula (Z-7) is preferable.

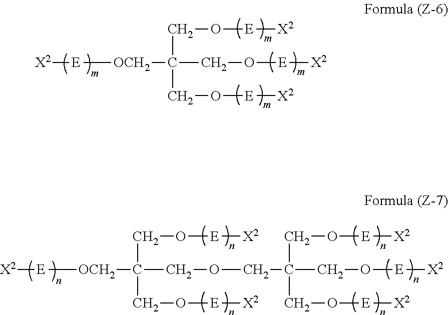

In Formula (Z-6), E each independently represents —((CH₂)_{y}CH₂O)-*2 or —((CH₂)_{y}CH(CH₃)O)-*2, y each independently represents an integer of 0 to 10, and m each independently represents an integer of 0 to 10. X² represents a (meth)acryloyl group. *2 represents a binding position on the X² side.

Particularly, in view of further improving the effects of the present invention, an aspect is preferable in which all of four n's represent 0, and an aspect is more preferable in which all of four m's represent 1, E represents —((CH₂)_{y}CH₂O)-*2, and all of four y's represents 1.

That is, a compound represented by Formula (Z-6-1) is more preferable.

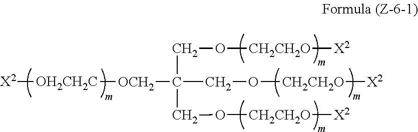

All of four m's represent 0 or 1, and X² represents a (meth)acryloyl group.

In Formula (Z-7), E each independently represents —((CH₂)_{y}CH₂O)-*2 or —((CH₂)_{y}CH(CH₃)O)-*2, y each independently represents an integer of 0 to 10, and n each independently represents an integer of 0 to 10. X² represents a (meth)acryloyl group. *2 represents a binding position on the X² side.

Particularly, in view of further improving the effects of the present invention, an aspect is preferable in which all of six m's represent 0.

That is, a compound represented by Formula (Z-7-1) is more preferable.

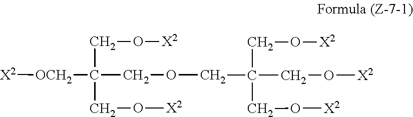

X² represents a (meth)acryloyl group.

Particularly, in view of further improving the evaluation result of temporal stability against delay and the evaluation result of post-development lenticulation, it is preferable that the third polymerizable compound contains a polymerizable compound which is a compound different from the first polymerizable compound and the second polymerizable compound and has a plurality of polymerizable groups, in which a ratio obtained by dividing the number of the polymerizable groups by the molecular weight of the polymerizable compound is equal to or higher than 0.0100 and less than 0.0120.

The ratio obtained by dividing the number of the polymerizable group by the molecular weight of the polymerizable compound (number of polymerizable groups/molecular weight) is preferably 0.0103 to 0.0115.

The content of the third polymerizable compound in the curable composition with respect to the total solid content of the curable composition is preferably 0.1% to 30% by mass, more preferably 1% to 25% by mass, and even more preferably 3% to 20% by mass.

One kind of third polymerizable compound may be used singly, or two or more kinds of third polymerizable compounds may be used in combination. In a case where two or more kinds of third polymerizable compounds are used in combination, the total content thereof is preferably within the above range.

The polymerizable compound may contain other polymerizable compounds in addition to the first polymerizable compound, the second polymerizable compound, and the third polymerizable compound.

In view of further improving the evaluation result of temporal stability against delay and the evaluation result of post-development lenticulation, it is preferable that the curable composition contains at least 4 or more kinds of compounds as the polymerizable compound. For example, a case where the curable composition contains one kind of first polymerizable compound, one kind of second polymerizable compound, and two kinds of third polymerizable compounds corresponds to an aspect in which the curable composition contains 4 kinds of compounds.

The number of kinds of polymerizable compounds in the curable composition is preferably 4 or greater, more preferably 4 to 6, and even more preferably 4 or 5.

Details of the reason why the aforementioned effects are obtained are unclear. Presumably, in a case where the curable composition contains polymerizable compounds having different numbers of polymerizable groups, the molecular weight may easily vary between cross-linking points in the cured film, the stress of shrinkage occurring in the cured film may be easily dispersed by curing, and accordingly, the evaluation result of post-development lenticulation may be improved.

In view of further improving the evaluation results of temporal stability against delay time and the evaluation results of post-development lenticulation, the curable composition preferably contains at least 3 or more kinds of compounds having different numbers of polymerizable groups as the polymerizable compound, and more preferably contains 4 or more kinds of compounds having different numbers of polymerizable groups as the polymerizable compound. For example, in a case where the curable composition contains the first polymerizable compound having 6 polymerizable groups, the second polymerizable compound having 5 polymerizable groups, the second polymerizable compound having 3 polymerizable groups, the third polymerizable compound having 6 polymerizable groups, and the third polymerizable compound having 4 polymerizable groups, both the first polymerizable compound having 6 polymerizable groups and third polymerizable compound having 6 polymerizable groups are a compound having 6 polymerizable groups. Therefore, such a curable composition corresponds to an aspect in which the curable composition contains 4 kinds of compounds having different numbers of polymerizable groups.

As an aspect of the polymerizable compound in the curable composition, an aspect is preferable in which the polymerizable compound contains the compound represented by Formula (Z-1), the compound represented by Formula (Z-5) (preferably the compound represented by Formula (Z-5-1)), the compound represented by Formula (Z-6) (preferably the compound represented by Formula (Z-6-1)), and the compound represented by Formula (Z-7) (preferably the compound represented by Formula (Z-7-1)). Furthermore, in the above aspect, the polymerizable compound may contain the compound represented by Formula (Z-4) (preferably the compound represented by Formula (Z-4-1)).

The components in the curable composition can be analyzed by combining known methods. For example, for mass spectrometry, liquid chromatography mass spectrometry using an electrospray ionization method (preferably in a positive mode) may be used.

<Optional Components>

The curable composition may contain other components in addition to carbon black and the polymerizable compound as long as the curable composition brings about the effects of the present invention. Examples of those other components include a polymerization initiator, a resin, a polymerization inhibitor, a surfactant, a colorant, an ultraviolet absorber, a silane coupling agent, and a solvent. Hereinafter, the optional components to be incorporated into the curable composition will be specifically described.

<Polymerization Initiator>

The curable composition may contain a polymerization initiator.

The type of the polymerization initiator is not particularly limited, and examples thereof include known polymerization initiators. Examples of the polymerization initiator include a photopolymerization initiator, a thermal polymerization initiator, and the like. Among these, a photopolymerization initiator is preferable. It is also preferable that the polymerization initiator is selected from a polymerization initiator without colorability and a polymerization initiator having high fading properties. As the polymerization initiator, a so-called radical polymerization initiator is preferable.

Examples of the thermal polymerization initiator include an azo compound such as 2,2′-azobisisobutyronitrile (AIBN), 3-carboxypropionitrile, azobismalenonitrile, or dimethyl-(2,2′)-azobis(2-methylpropionate) [V-601] and an organic peroxide such as benzoyl peroxide, lauroyl peroxide, or potassium persulfate.

Examples of the thermal polymerization initiator include the compounds described in “Ultraviolet Curing System”, Kiyomi Kato, SOGO GIJUTSU CENTER, 1989, pp. 65-148, and the like.

It is preferable that the curable composition contains a photopolymerization initiator.

The photopolymerization initiator is not particularly limited as long as it can initiate the polymerization of a polymerizable compound. Examples thereof include known visible ray photopolymerization initiators. As the photopolymerization initiator, for example, a compound exhibiting photosensitivity in a range of ultraviolet rays to visible rays is preferable. Furthermore, the photopolymerization initiator may be an activator which generates active radicals by interacting in a certain way with a photoexcited sensitizer or an initiator which initiates cationic polymerization according to the type of the polymerizable compound.

Furthermore, it is preferable that the curable composition contains, as a photopolymerization initiator, at least one kind of compound having at least a molar absorption coefficient which is approximately 50 in a range of about 300 to 800 nm (more preferably 330 to 500 nm).

Examples of the photopolymerization initiator include a halogenated hydrocarbon derivative (for example, a halogenated hydrocarbon derivative containing a triazine skeleton, a halogenated hydrocarbon derivative containing an oxadiazole skeleton, or the like), an α-aminoketone compound, an acyl phosphine compound such as or acyl phosphine oxide, a hexaaryl biimidazole compound, an oxime compound such as an oxime derivative, an organic peroxide, a thio compound, a ketone compound, an aromatic onium salt, an α-aminoketone compound (preferably an α-aminoacetophenone compound), hydroxyacetophenone, and the like.

It is preferable that the curable composition contains an α-aminoketone-based polymerization initiator. In view of improving a proportion of residual film which will be described later, it is also preferable that the curable composition contains an oxime ester-based polymerization initiator (hereinafter, referred to as “oxime compound” as well) together with the α-aminoketone-based polymerization initiator.

As the photopolymerization initiator, for example, the aminoacetophenone-based initiator described in JP1998-291969A (JP-H10-291969A) and the acyl phosphine-based initiator described in JP4225898B can be used. The contents of the above documents are incorporated into the present specification.

Examples of the hydroxyacetophenone compound include IRGACURE-184, DAROCUR-1173, IRGACURE-500, IRGACURE-2959, and IRGACURE-127 (trade names: manufactured by BASF SE).

Examples of the α-aminoketone compound (preferably an α-aminoacetophenone compound) include commercial products such as IRGACURE-907, IRGACURE-369, and IRGACURE-379EG (trade names: manufactured by BASF SE).

Examples of the acyl phosphine compound include IRGACURE-819 and IRGACURE-TPO (trade names: manufactured by BASF SE).

The oxime compound has higher sensitivity and higher polymerization efficiency. Consequently, even in a case where the curable composition containing the oxime compound contains a large amount of pigments, the curable composition has better curing properties.

As the oxime compound, it is possible to use the compound described in JP2001-233842A, the compound described in JP2000-080068A, and the compound described in JP2006-342166A. The contents of the above documents are incorporated into the present specification.

Examples of the oxime compound include 3-benzoyloxyiminobutan-2-one, 3-aceotxyiminobutan-2-one, 3-propionyloxyiminobutane-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, 2-ethoxycarbonyloxyimino-1-phenylpropan-1-one, and the like.

Examples of the oxime compound also include the compounds described in J. C. S. Perkin II (1979) pp. 1653-1660, J. C. S. Perkin II (1979) pp. 156-162, Journal of Photopolymer Science and Technology (1995) pp. 202-232, JP2000-066385A, JP2000-080068A, JP2004-534797A, and JP2006-342166A, and the like. The contents of the above documents are incorporated into the present specification.

Examples of commercial products of the oxime compound include IRGACURE-OXE01 (manufactured by BASF SE), IRGACURE-OXE02 (manufactured by BASF SE), IRGACURE-OXE03 (manufactured by BASF SE), or IRGACURE-OXE04 (manufactured by BASF SE), TR-PBG-304 (manufactured by TRONLY), ADEKA ARKLS NCI-831 and ADEKA ARKLS NCI-930 (manufactured by ADEKA CORPORATION), N-1919 (carbazole.oxime ester skeleton-containing photoinitiator (manufactured by ADEKA CORPORATION)), NCI-730 (manufactured by ADEKA CORPORATION), and the like.

Examples of oxime compounds other than the above include the compound described in JP2009-519904A in which oxime is linked to N-position of carbazole; the compound described in U.S. Pat. No. 7,626,957B in which a hetero substituent is introduced into a benzophenone moiety; the compound described in JP2010-015025A and US2009/292039A in which a nitro group is introduced into the moiety of a coloring agent; the ketoxime compound described in WO2009/131189A; the compound described in U.S. Pat. No. 7,556,910B that contains a triazine skeleton and an oxime skeleton in the same molecule; the compound described in JP2009-221114A that has absorption maximum wavelength at 405 nm and exhibits excellent sensitivity with respect to a light source of g-line; and the like.

Furthermore, the compounds described in paragraphs “0274” and “0275” in JP2013-029760A can also be used, and the contents of these paragraphs are incorporated into the present specification.

As the oxime compound, a compound containing a structure represented by Formula (OX-1) is preferable. In the oxime compound, the N—O bond may be an (E) isomer or a (Z) isomer. As the oxime compound, the (E) isomer and the (Z) isomer may be used in combination.

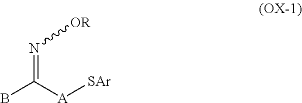

In Formula (OX-1), R and B each independently represent a monovalent substituent, A represents a divalent organic group, and Ar represents an aryl group.

As the monovalent substituent represented by R in Formula (OX-1), a group of monovalent nonmetallic atoms is preferable.

Examples of the group of monovalent nonmetallic atoms include an alkyl group, an aryl group, an acyl group, an alkoxycarbonyl group, an aryloxycarbonyl group, a heterocyclic group, an alkylthiocarbonyl group, an arylthiocarbonyl group, and the like. These groups may have one or more substituents. Furthermore, each of the substituents may be further substituted with another substituent.

Examples of the substituent include a halogen atom, an aryloxy group, an alkoxycarbonyl group, an aryloxycarbonyl group, an acyloxy group, an acyl group, an alkyl group, an aryl group, and the like.

As the monovalent substituent represented by B in Formula (OX-1), an aryl group, a heterocyclic group, an arylcarbonyl group, or a heterocyclic carbonyl group is preferable, and an aryl group or a heterocyclic group is more preferable. These groups may have one or more substituents. Examples of the substituents are the same as the examples of the aforementioned substituents.

As the divalent organic group represented by A in Formula (OX-1), an alkylene group having 1 to 12 carbon atoms, a cycloalkylene group, or an alkynylene group is preferable. These groups may have one or more substituents. Examples of the substituents include the substituents described above.

As the photopolymerization initiator, a fluorine atom-containing oxime compound can also be used. Specific examples of the fluorine atom-containing oxime compound include the compound described in JP2010-262028A; the compounds 24 and 36 to 40 described in JP2014-500852A; the compound (C-3) described in JP2013-164471A; and the like. The contents of the above documents are incorporated into the present specification.

As the photopolymerization initiator, compounds represented by Formulae (1) to (4) can also be used.

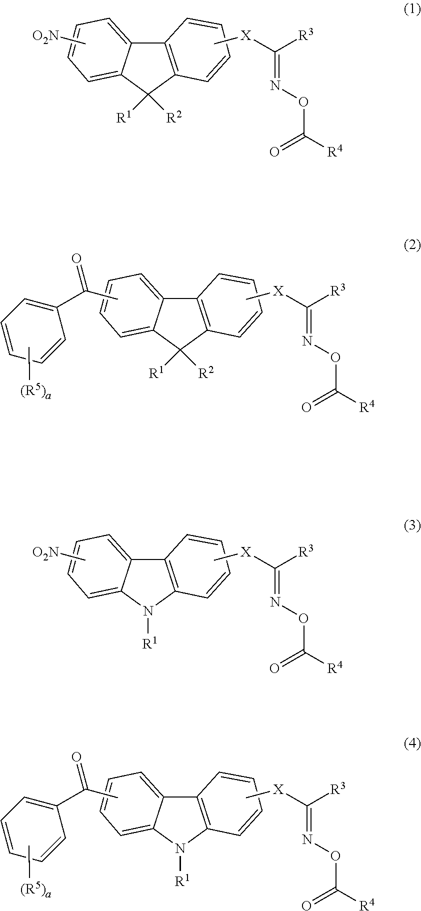

In Formula (1), R¹ and R² each independently represent an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms. In a case where each of R¹ and R² each represent a phenyl group, the phenyl groups may form a fluorene group by being bonded to each other. R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a single bond or a carbonyl group.

R¹, R², R³, and R⁴ in Formula (2) have the same definition as R¹, R², R³, and R⁴ in Formula (1). R⁵ represents —R⁶, —OR⁶, —SR⁶, —COR⁶, —CONR⁶R⁶, —NR⁶COR⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a single bond or a carbonyl group, and a represents an integer of 0 to 4.

In Formula (3), R¹ represents an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms, R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a single bond or a carbonyl group.

R¹, R³, and R⁴ in Formula (4) have the same definition as R¹, R³, and R⁴ in Formula (3). R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a single bond or a carbonyl group, and a represents an integer of 0 to 4.

In Formula (1) and Formula (2), R¹ and R² preferably each independently represent a methyl group, an ethyl group, a n-propyl group, an i-propyl group, a cyclohexyl group, or a phenyl group. R³ preferably represents a methyl group, an ethyl group, a phenyl group, a tolyl group, or a xylyl group. R⁴ preferably represents an alkyl group having 1 to 6 carbon atoms or a phenyl group. R⁵ preferably represents a methyl group, an ethyl group, a phenyl group, a tolyl group, or a naphthyl group. X preferably represents a single bond.

In Formula (3) and Formula (4), R¹ preferably each independently represents a methyl group, an ethyl group, a n-propyl group, an i-propyl group, a cyclohexyl group, or a phenyl group. R³ preferably represents a methyl group, an ethyl group, a phenyl group, a tolyl group, or a xylyl group. R⁴ preferably represents an alkyl group having 1 to 6 carbon atoms or a phenyl group. R⁵ preferably represents a methyl group, an ethyl group, a phenyl group, a tolyl group, or a naphthyl group. X preferably represents a single bond.

Specific examples of the compounds represented by Formula (1) and Formula (2) include the compounds described in paragraphs “0076” to “0079” in JP2014-137466A, and the contents of the paragraphs are incorporated into the present specification.

Specific examples of oxime compounds preferably used in the curable composition will be shown below. As the oxime compounds, the compounds described in Table 1 in WO2015/036910A can also be used, and the content of the document is incorporated into the present specification.

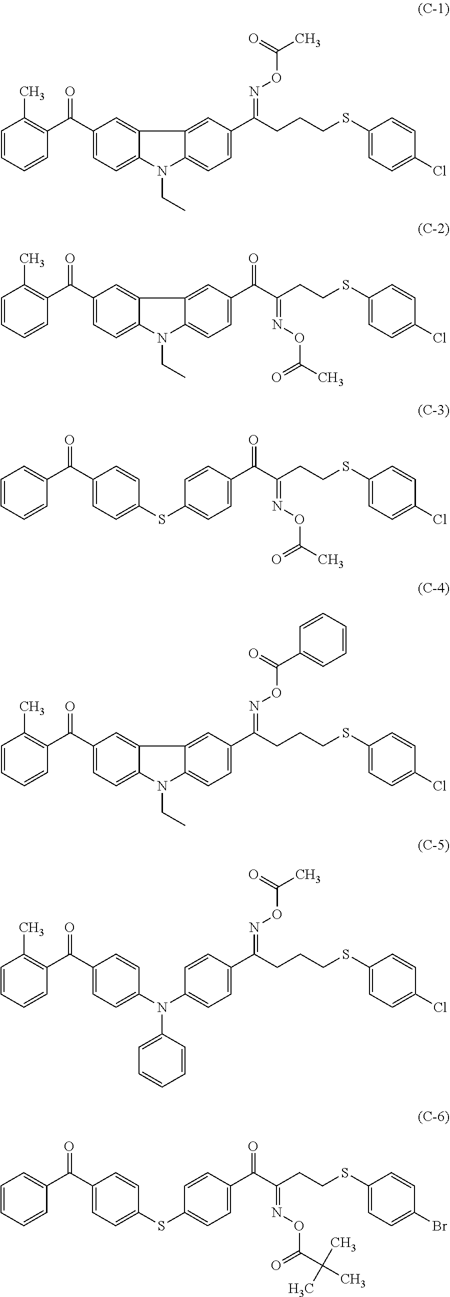 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

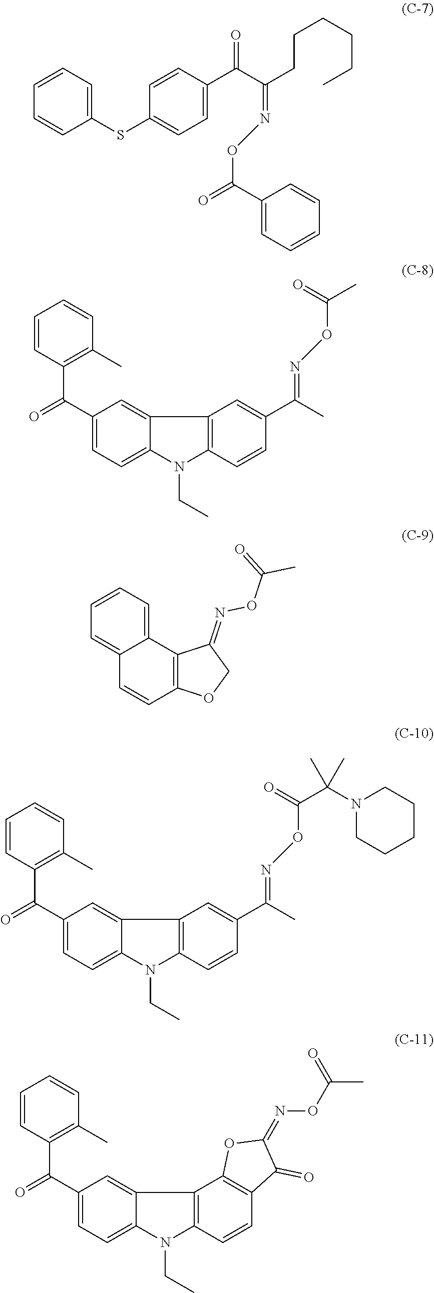

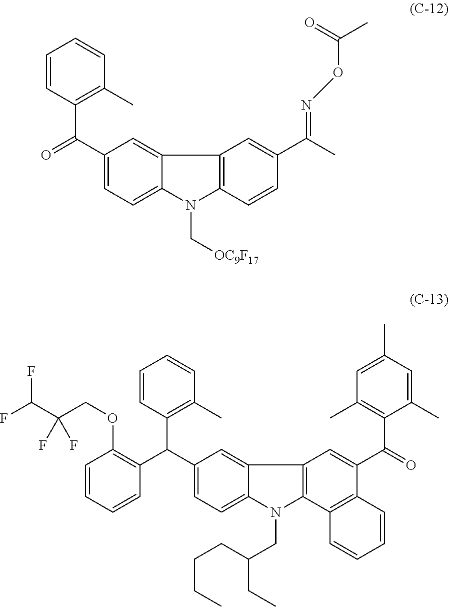

The oxime compound has a maximum absorption wavelength preferably in a range of a wavelength of 350 to 500 nm, and more preferably in a range of a wavelength of 360 to 480 nm. As the oxime compound, a compound having a high absorbance at 365 nm and 405 nm is even more preferable.

From the viewpoint of sensitivity, a molar absorption coefficient of the oxime compound at 365 nm or 405 nm is preferably 1,000 to 300,000, more preferably 2,000 to 300,000, and even more preferably 5,000 to 200,000.

The molar absorption coefficient of the oxime compound can be measured by known methods. For example, it is preferable that the molar absorption coefficient is measured using an ultraviolet/visible spectrophotometer (Cary-5 spectrophotometer manufactured by Varian, Inc.) and an ethyl acetate at a concentration of 0.01 g/L.

If necessary, two or more kinds of photopolymerization initiators may be used in combination.

As the photopolymerization initiator, it is also possible to use the compounds described in paragraph “0052” in JP2008-260927A, paragraphs “0033” to “0037” in JP2010-097210A, and paragraph “0044” in JP2015-068893A, and the contents of the above paragraphs are incorporated into the present specification.

The content of the polymerization initiator in the curable composition is not particularly limited. However, the content of the polymerization initiator with respect to the total solid content of the curable composition is preferably 0.1% to 20% by mass.

One kind of polymerization initiator may be used singly, or two or more kinds of polymerization initiators may be used in combination. In a case where two or more kinds of polymerization initiators are used in combination, the total content thereof is preferably within the above range.

<Resin>

The curable composition may contain a resin. Examples of the resin include a dispersant, an alkali-soluble resin, and the like.

The content of the resin in the curable composition is not particularly limited. However, the content of the resin with respect to the total solid content of the curable composition is preferably 5% to 45% by mass.

One kind of resin may be used singly, or two or more kinds of resins may be used in combination. In a case where two or more kinds of resins are used in combination, the total content thereof is preferably within the above range.

(Dispersant)

It is preferable that the curable composition contains a dispersant (corresponding to a resin).

The dispersant mainly functions as a dispersant for carbon black and other colorants (particularly, a pigment).

The content of the dispersant in the curable composition is not particularly limited. In order for the curable composition to have better temporal stability and better patterning properties, the content of the dispersant with respect to the total solid content of the curable composition is preferably 5% to 40% by mass.

One kind of dispersant may be used singly, or two or more kinds of dispersants may be used in combination. In a case where two or more kinds of dispersants are used in combination, the total content thereof is preferably within the above range.

As the dispersant, known dispersants can be used without particular limitation.

Examples of the dispersant include a polymer dispersant. Examples of the polymer dispersant include polyamide amine and a salt thereof, polycarboxylic acid and a salt thereof, a high-molecular-weight unsaturated acid ester, modified polyurethane, modified polyester, modified poly(meth)acrylate, a (meth)acrylic copolymer, and a naphthalenesulfonic acid formalin condensate.

Furthermore, examples of the dispersant also include a polyoxyethylene alkyl phosphoric acid ester, polyoxyethylene alkyl amine, and a pigment derivative.

Among these, a polymer compound is preferred as the dispersant. The polymer compound can be further classified into a linear polymer, a terminal-modified polymer, a graft polymer, and a block polymer based on the structure.

The polymer compound functions to prevent the reaggregation of carbon black or a pigment by being adsorbed onto the surface of carbon black or a pigment. Therefore, as the polymer compound, a terminal-modified polymer, a graft polymer (containing a polymer chain), and a block polymer are preferable which contain a moiety anchored to the surface of carbon black or a pigment.

It is preferable that the polymer compound contains a structural unit containing a graft chain. In the present specification, “structural unit” has the same definition as “repeating unit”.

The polymer compound which contains the structural unit containing a graft chain exhibits higher affinity with a solvent. Because the polymer compound which contains a structural unit containing a graft chain exhibits higher affinity with a solvent, the polymer compound more easily disperses carbon black or a pigment and makes it more difficult for the initial dispersion state to change even after the lapse of time after carbon black or the pigment is dispersed. In addition, because the polymer compound which contains a structural unit containing a graft chain contains a graft chain, the polymer compound exhibits higher affinity with the polymerizable compound, which will be described later, and/or other components and the like. Consequently, at the time of alkali development which will be described later, the polymer compound which contains a structural unit containing a graft chain hardly generates residues resulting from an unreacted polymerizable compound and the like.

The longer the graft chain (the larger the formula weight), the stronger the steric repulsion effect, and hence the dispersibility of carbon black or a pigment is improved. In contrast, in a case where the graft chain is too long, the adsorptivity with respect to carbon black or a pigment is reduced, and hence the dispersibility of carbon black or the pigment tends to be reduced. Therefore, the number of atoms (except for hydrogen atoms) constituting the graft chain is preferably 40 to 10,000, more preferably 50 to 2,000, and even more preferably 60 to 500.

Herein, the graft chain means a portion from the base of a main chain of the polymer compound (an atom bonded to the main chain in a group which is branched off the main chain) to the terminal of a group branching off the main chain.

As the graft chain, a polymer chain containing a polymer structure is preferable. The polymer structure that the polymer chain contains is not particularly limited, and examples thereof include a poly(meth)acrylate structure (for example, a poly(meth)acryl structure), a polyester structure, a polyurethane structure, a polyurea structure, a polyamide structure, a polyether structure, and the like.

In order for higher affinity to be exhibited with a polymer chain and a solvent and for the polymer compound to more easily disperse carbon black or a pigment, the polymer chain preferably contains at least one kind of structure selected from the group consisting of a polyester structure, a polyether structure, and a poly(meth)acrylate structure, and more preferably contains at least one kind of structure selected from the group consisting of a polyester structure and a polyether structure.

Examples of commercial macromonomers, which correspond to the structural unit containing a polymer chain contained in the polymer compound and can be used for synthesizing the polymer compound, include AA-6, AA-10, AB-6, AS-6, AN-6, AW-6, AA-714, AY-707, AY-714, AK-5, AK-30, and AK-32 (trade names, manufactured by TOAGOSEI CO., LTD.); BLEMMER PP-100, BLEMMER PP-500, BLEMMER PP-800, BLEMMER PP-1000, BLEMMER 55-PET-800, BLEMMER PME-4000, BLEMMER PSE-400, BLEMMER PSE-1300, and BLEMMER 43PAPE-600B (trade names, manufactured by NOF CORPORATION); and the like.

The aforementioned dispersant preferably contains at least one kind of structure selected from the group consisting of polymethyl acrylate, polymethyl methacrylate, and cyclic or chain-like polyester, more preferably contains at least one kind of structure selected from the group consisting of polymethyl acrylate, polymethyl methacrylate, and chain-like polyester, and even more preferably contains at least one kind of structure selected from the group consisting of a polymethyl acrylate structure, a polymethyl methacrylate structure, a polycaprolactone structure, and a polyvalerolactone structure.

The dispersant may contain only one kind of the aforementioned structure in a molecule or plural kinds of the aforementioned structures in a molecule.

The polycaprolactone structure refers to a structure containing a structure, which is obtained by ring opening of ε-caprolactone, as a repeating unit. The polyvalerolactone structure refers to a structure containing a structure, which is obtained by ring opening of δ-valerolactone, as a repeating unit.

It is preferable that the polymer compound contains a hydrophobic structural unit different from the structural unit containing a graft chain (that is, a hydrophobic structural unit which does not correspond to the structural unit containing a graft chain). Here, in the present specification, the hydrophobic structural unit is a structural unit which does not contain an acid group (for example, a carboxylic acid group, a sulfonic acid group, a phosphoric acid group, a phenolic hydroxyl group, or the like).

As the hydrophobic structural unit, a structural unit derived from (corresponding to) a compound (monomer) having a ClogP value, which will be described later, equal to or greater than 1.2 is preferable, and a structural unit derived from a compound having a ClogP value of 1.2 to 8.0 is more preferable.

The ClogP value is a value calculated by a program “CLOGP” available from Daylight Chemical Information System, Inc. This program provides a value of “calculated log P” calculated by the fragment approach (see the following documents) of Hansch and Leo. The fragment approach is based on the chemical structure of a compound. In this method, the chemical structure is divided into partial structures (fragments), and degrees of contribution to log P that are assigned to the fragments are summed up, thereby estimating the log P value of the compound. Details of the method are described in the following documents. In the present invention, a ClogP value calculated by a program CLOGP v 4.82 is used.

A. J. Leo, Comprehensive Medicinal Chemistry, Vol. 4, C. Hansch, P. G. Sammnens

J. B. Taylor and C. A. Ramsden, Eds., p. 295, Pergamon press, 1990

C. Hansch & A. J. Leo. Substituent Constants For Correlation Analysis in Chemistry and Biology. John Wiley & Sons.

A. J. Leo. Calculating logPoct from structure. Chem. Rev., 93, 1281-1306, 1993.

log P means a common logarithm of a partition coefficient P. log P is a value of physical properties that shows how a certain organic compound is partitioned in an equilibrium of two-phase system consisting of oil (generally, 1-octanol) and water by using a quantitative numerical value. log P is represented by the following formula.

log P=log(Coil/Cwater)

In the formula, Coil represents a molar concentration of a compound in an oil phase, and Cwater represents a molar concentration of the compound in a water phase.

The greater the positive log P value based on 0, the higher the oil solubility. The greater the absolute value of negative log P, the higher the water solubility. The value of log P is negatively correlated with the water solubility of an organic compound, and widely used as a parameter for estimating the hydrophilicity and hydrophobicity of an organic compound.

It is preferable that the polymer compound contains a functional group capable of interacting with carbon black or a pigment. That is, it is preferable that the polymer compound further contains a structural unit which contains a functional group capable of interacting with carbon black or a pigment.

Examples of the functional group capable of interacting with carbon black or a pigment include an acid group, a basic group, a coordinating group, a reactive functional group, and the like.

In a case where the polymer compound contains an acid group, a basic group, a coordinating group, or a reactive functional group, it is preferable that the polymer compound contains each of a structural unit containing an acid group, a structural unit containing a basic group, a structural unit containing a coordinating group, or a reactive structural unit.

The polymer compound containing an acid group exhibits higher affinity with the solvent which will be described later. Accordingly, the curable composition which contains the polymer compound containing an acid group has better coating properties.

Presumably, this is because the acid group in the structural unit containing an acid group may easily interact with carbon black or a pigment, the polymer compound may stably disperse the carbon black or the pigment, the viscosity of the polymer compound dispersing the carbon black or the pigment may be reduced, and hence the polymer compound may also be easily dispersed in a stable manner.

The structural unit containing an alkali-soluble group as an acid group may be the same as or different from the structural unit containing a graft chain described above.

In the present specification, the structural unit containing an alkali-soluble group as an acid group means a structural unit different from the hydrophobic structural unit described above (that is, the structural unit does not correspond to the hydrophobic structural unit).

Among functional groups capable of interacting with carbon black or a pigment, examples of acid groups include a carboxylic acid group, a sulfonic acid group, a phosphoric acid group, and a phenolic hydroxyl group. Among these, at least one kind of acid group selected from the group consisting of a carboxylic acid group, a sulfonic acid group, and a phosphoric acid group is preferable, and a carboxylic acid group is more preferable because this group exhibits higher adsorptivity with respect to carbon black or a pigment and has better dispersibility.

That is, it is preferable that the polymer compound further contains a structural unit which contains at least one kind of acid group selected from the group consisting of a carboxylic acid group, a sulfonic acid group, and a phosphoric acid group.

The polymer compound may have one kind of structural unit containing an acid group or two or more kinds of structural units containing an acid group.

The polymer compound may or may not contain the structural unit containing an acid group.

In the polymer compound, the content of the structural unit containing an acid group with respect to the total mass of the polymer compound is preferably 5% to 80% by mass, and more preferably 10% to 60% by mass in view of further inhibiting the image intensity from being damaged by alkali development.

Among the functional groups capable of interacting with carbon black or a pigment, examples of basic groups include a primary amino group, a secondary amino group, a tertiary amino group, a hetero ring containing a N atom, an amide group, and the like. Among these, a tertiary amino group is preferable because this exhibits higher adsorptivity with respect to carbon black or a pigment and has better dispersibility. The polymer compound may contain one kind of basic group or two or more kinds of basic groups. The polymer compound may or may not contain the structural unit containing a basic group.

In the polymer compound, the content of the structural unit containing a basic group with respect to the total mass of the polymer compound is preferably 0.01% to 50% by mass, and more preferably 0.01% to 30% by mass because then the curable composition has better developability (because then it is more difficult for the alkali development to be hindered).

Among the functional groups capable of interacting with carbon black or a pigment, examples of coordinating groups and reactive functional groups include an acetyl acetoxy group, a trialkoxysilyl group, an isocyanate group, an acid anhydride group, an acid chloride group, and the like. Among these, acetyl acetoxy group is preferable because this exhibits higher adsorptivity with respect to carbon black or a pigment and more easily disperses carbon black or a pigment. The polymer compound may contain one kind of coordinating group and one kind of reactive functional group, or contain two or more kinds of coordinating groups and reactive functional groups. The polymer compound may or may not contain both the structural unit containing a coordinating group and the structural unit containing a reactive functional group.

In the polymer compound, the content of the structural unit containing a coordinating group and the reactive functional group with respect to the total mass of the polymer compound is preferably 10% to 80% by mass, and more preferably 20% to 60% by mass because then the curable composition has better developability (because then it is more difficult for the alkali development to be hindered).

In the polymer compound, from the viewpoint of the interaction with carbon black or a pigment, the temporal stability, and the permeability with respect to a developer, the content of the structural unit containing a functional group capable of interacting with carbon black or a pigment with respect to the total mass of the polymer compound is preferably 0.05% to 90% by mass, more preferably 1.0% to 80% by mass, and even more preferably 10% to 70% by mass.

For the purpose of improving various performances such as image intensity, as long as the effects of the present invention are not impaired, the polymer compound may further contain other structural units (for example, a structural unit containing a functional group or the like having affinity with the solvent used in a dispersion composition, and the like) that are different from the structural unit containing a graft chain, the hydrophobic structural unit, and the structural unit containing a functional group capable of interacting with carbon black or a pigment.

Examples of those other structural units include structural units derived from radically polymerizable compounds selected from the group consisting of acrylonitriles and methacrylonitriles, and the like.

The polymer compound may contain one kind of those other structural units or two or more kinds of those other structural units.

In the polymer compound, the content of those other structural units with respect to the total mass of the polymer compound is preferably 0% to 80% by mass, and more preferably 10% to 60% by mass. In a case where the content of those other structural units is 0% to 80% by mass, the curable composition has better pattern forming properties.

The acid value of the polymer compound is not particularly limited, but is preferably 0 to 250 mgKOH/g, more preferably 10 to 200 mgKOH/g, and even more preferably 20 to 120 mgKOH/g.

The acid value of the polymer compound can be calculated, for example, from the average content of acid groups in the polymer compound. Furthermore, by changing the content of the acid group-containing structural unit in the polymer compound, a polymer compound having the desired acid value can be obtained.

In order for the curable composition to have better developability and in order to make it more difficult for the obtained colored film to be peeled in the development step, the weight-average molecular weight of the polymer compound that is determined by Gel Permeation Chromatography (GPC) and expressed in terms of polystyrene is preferably 4,000 to 300,000, more preferably 5,000 to 200,000, even more preferably 6,000 to 100,000, and particularly preferably 10,000 to 50,000.

GPC is based on a method of using HLC-8020GPC (manufactured by Tosoh Corporation), TSKgel SuperHZM-H, TSKgel SuperHZ4000, and TSKgel SuperHZ2000 (manufactured by Tosoh Corporation, 4.6 mmID×15 cm) as columns, and tetrahydrofuran (THF) as an eluent. The polymer compound can be synthesized based on known methods.

Specific examples of the polymer compound include “DA-7301” manufactured by Kusumoto Chemicals. Ltd., “Disperbyk-101 (polyamidoamine phosphate), 107 (carboxylic acid ester), 110 (copolymer containing an acid group), 111 (phosphoric acid-based dispersant), 130 (polyamide), 161, 162, 163, 164, 165, 166, 170, and 190 (polymeric copolymer)” and “BYK-P104 and P105 (high-molecular-weight unsaturated polycarboxylic acid)” manufactured by BYKChemie GmbH, “EFKA 4047, 4050 to 4010 to 4165 (based on polyurethane), EFKA 4330 to 4340 (block copolymer), 4400 to 4402 (modified polyacrylate), 5010 (polyester amide), 5765 (high-molecular-weight polycarboxylate), 6220 (aliphatic polyester), 6745 (phthalocyanine derivative), and 6750 (azo pigment derivative” manufactured by EFKA, “AJISPER PB821, PB822, PB880, and PB881” manufactured by Ajinomoto Fine-Techno Co., Inc., “FLOWLEN TG-710 (urethane oligomer)” and “POLYFLOW No. 50E, No. 300 (acrylic copolymer)” manufactured by KYOEISHA CHEMICAL Co., LTD, “DISPARLON KS-860, 873SN, 874, #2150 (aliphatic polyvalent carboxylic acid), #7004 (polyether ester), DA-703-50, DA-705, and DA-725” manufactured by Kusumoto Chemicals. Ltd., “DEMOL RN, N (naphthalenesulfonic acid formalin polycondensate), MS, C, and SN-B (aromatic sulfonic acid formalin polycondensate)”, “HOMOGENOL L-18 (polymeric polycarboxylic acid)”, “EMULGEN 920, 930, 935, and 985 (polyoxyethylene nonylphenyl ether)”, and “ACETAMIN 86 (stearylamine acetate)” manufactured by Kao Corporation, “SOLSPERSE 5000 (phthalocyanine derivative), 22000 (azo pigment derivative), 13240 (polyester amine), 3000, 12000, 17000, 20000, 27000 (polymer containing a functional portion on a terminal portion), 24000, 28000, 32000, and 38500 (graft copolymer)” manufactured by Lubrizol Japan Limited, “NIKKOL T106 (polyoxyethylene sorbitan monooleate), and MYS-IEX (polyoxyethylene monostearate)” manufactured by Nikko Chemicals Co., Ltd., HINOACT T-8000E and the like manufactured by Kawaken Fine Chemicals Co., Ltd., an organosiloxane polymer KP341 manufactured by Shin-Etsu Chemical Co., Ltd., “W001: cationic surfactant” manufactured by Yusho Co., Ltd., nonionic surfactants such as polyoxyethylene lauryl ether, polyoxyethylene stearyl ether, polyoxyethylene oleyl ether, polyoxyethylene octyl phenyl ether, polyoxyethylene nonylphenyl ether, polyethylene glycol dilaurate, polyethylene glycol distearate, and a sorbitan fatty acid ester, anionic surfactants such as “W004, W005, and W017”, polymer dispersants such as “EFKA-46, EFKA-47, EFKA-47EA, EFKA polymer 100, EFKA polymer 400, EFKA polymer 401, and EFKA polymer 450” manufactured by MORISHITA & CO., LTD., and “DISPERSE AID 6, DISPERSE AID 8, DISPERSE AID 15, and DISPERSE AID 9100” manufactured by SAN NOPCO LIMITED, “ADEKA PLURONIC L31, F38, L42, L44, L61, L64, F68, L72, P95, F77, P84, F87, P94, L101, P103, F108, L121, and P-123” manufactured by ADEKA CORPORATION, “IONET (trade name) S-20” manufactured by Sanyo Chemical Industries, Ltd., and the like. Furthermore, ACRYBASE FFS-6752, ACRYBASE FFS-187, ACRYCURE RD-F8, and CYCLOMER P can also be used.

Furthermore, it is also possible to use DISPERBYK-130, DISPERBYK-140, DISPERBYK-142, DISPERBYK-145, DISPERBYK-180, DISPERBYK-187, DISPERBYK-191, DISPERBYK-2001, DISPERBYK-2010, DISPERBYK-2012, DISPERBYK-2025, and BYK-9076 manufactured by BYKChemie GmbH, AJISPER PB821, AJISPER PB822, and AJISPER PB881 manufactured by Ajinomoto Fine-Techno Co., Inc., and the like.

One kind of these polymer compounds may be used singly, or two or more kinds of these polymer compounds may be used in combination.

As the polymer compound, the compounds described in paragraphs “0127” to “0129” in JP2013-249417A can also be used, and the contents of the paragraphs are incorporated into the present specification.

Furthermore, as a dispersant, it is also possible to use the graft copolymers described in paragraphs “0037” to “0115” in JP2010-106268A (paragraphs “0075” to “0133” in US2011/0124824A corresponding to JP2010-106268A), and the contents of the paragraphs are incorporated into the present specification.

In addition, as a dispersant, it is also possible to use the polymer compounds described in paragraphs “0028” to “0084” in JP2011-153283A (paragraphs “0075” to “0133” in US2011/0279759A corresponding to JP2011-153283A) that contain a constituent component containing a side chain structure formed by bonding of acidic groups through a linking group, and the contents of the paragraphs are incorporated into the present specification.

Moreover, as a dispersant, the resins described in paragraphs “0033” to “0049” in JP2016-109763A can also be used, and the contents of the paragraphs are incorporated into the present specification.

(Alkali-Soluble Resin)

It is preferable that the curable composition contains an alkali-soluble resin (corresponding to a resin). The alkali-soluble resin means a resin which is dissolved in an alkali solution.

The content of the alkali-soluble resin in the curable composition is not particularly limited. In order for the curable composition to have better patterning properties, the content of the alkali-soluble resin with respect to the total solid content of the curable composition is preferably 0.5% to 30% by mass.

One kind of alkali-soluble resin may be used singly, or two or more kinds of alkali-soluble resins may be used in combination. In a case where two or more kinds of alkali-soluble resins are used in combination, the total content thereof is preferably within the above range.

It is preferable that the alkali-soluble resin has a curable group. As the curable group, a polymerizable group is preferable. Examples of the polymerizable group include the groups exemplified as the polymerizable group that the first polymerizable compound has.

It is preferable that the alkali-soluble resin has a cardo structure.

Examples of the alkali-soluble resin include a resin containing at least one alkali-soluble group in a molecule. Examples thereof include a polyhydroxystyrene resin, a polysiloxane resin, a (meth)acryl resin, a (meth)acrylamide resin, a (meth)acryl/(meth)acrylamide copolymer resin, an epoxy-based resin, a polyimide resin, and the like.

Specific examples of the alkali-soluble resin include a copolymer of an unsaturated carboxylic acid and an ethylenically unsaturated compound.

The unsaturated carboxylic acid is not particularly limited, and examples thereof include monocarboxylic acids such as (meth)acrylic acid, crotonic acid, and vinyl acetate; dicarboxylic acid such as itaconic acid, maleic acid, or fumaric acid or an acid anhydride of these; polyvalent carboxylic acid monoesters such as mono(2-(meth)acryloyloxyethyl)phthalate; and the like.

Examples of copolymerizable ethylenically unsaturated compounds include methyl (meth)acrylate and the like. Furthermore, it is also possible to use the compounds described in paragraph “0027” in JP2010-097210A and paragraphs “0036” and “0037” in JP2015-068893A, and the contents of the paragraphs are incorporated into the present specification.

Furthermore, copolymerizable ethylenically unsaturated compounds containing an ethylenically unsaturated group on a side chain may also be used in combination. As the ethylenically unsaturated group, a (meth)acrylic acid group is preferable. An acrylic resin containing an ethylenically unsaturated group on a side chain can be obtained, for example, by addition-reacting a carboxylic acid group of an acrylic resin containing a carboxylic acid group with an ethylenically unsaturated compound containing a glycidyl group or an alicyclic epoxy group.

As the alkali-soluble resin, for example, it is possible to use the radical polymer containing a carboxylic acid group on a side chain described in JP1984-044615A (JP-S59-044615A), JP1979-034327B (JP-S54-034327B), JP1983-012577B (JP-S58-012577B), JP1979-025957B (JP-S54-025957B), JP1979-092723A (JP-S54-092723A), JP1984-053836A (JP-S59-053836A), and JP1984-071048A (JP-S59-071048A); the acetal-modified polyvinyl alcohol-based binder resin containing an alkali-soluble group described in EP993966B, EP1204000B, and JP2001-318463A; polyvinyl pyrrolidone; polyethylene oxide; polyether as a product of a reaction between alcohol-soluble nylon, 2,2-bis-(4-hydroxyphenyl)-propane, and epichlorohydrin; the polyimide resin described in WO2008/123097A; and the like.

As the alkali-soluble resin, the compounds described in paragraphs “0225” to “0245” in JP2016-075845A can also be used, and the contents of the paragraphs are incorporated into the present specification.

As the alkali-soluble resin, a polyimide precursor can also be used. The polyimide precursor means a resin obtained by causing an addition polymerization reaction between a compound containing an acid anhydride group and a diamine compound at a temperature of 40° C. to 100° C.

<Polymerization Inhibitor>

The curable composition may contain a polymerization inhibitor. In a case where the curable composition contains a polymerization inhibitor, it is possible to inhibit the polymerizable compound in the curable composition from being unintentionally polymerized. Therefore, the curable composition has better temporal stability. Furthermore, because the unintended polymerization of the polymerizable compound in the curable composition is inhibited, the curable composition has better patterning properties.

Examples of the polymerization inhibitor include a phenol-based polymerization inhibitor (for example, p-methoxyphenol, 2,5-di-tert-butyl-4-methylphenol, 2,6-di-tert-butyl-4-methylphenol, 4,4′-thiobis(3-methyl-6-t-butylphenol), 2,2′-methylenebis(4-methyl-6-t-butylphenol), 4-methoxynaphthaol, or the like), a hydroquinone-based polymerization inhibitor (for example, hydroquinone, 2,6-di-tert-butylhydroquinone, or the like); a quinone-based polymerization inhibitor (for example, benzoquinone or the like), a free radical-based polymerization inhibitor (for example, a 2,2,6,6-tetramethylpiperidin-1-oxyl free radical, a 4-hydroxy-2,2,6,6-tetramethylpiperidin-1-oxyl free radical, or the like); a nitrobenzene-based polymerization inhibitor (for example, nitrobenzene, 4-nitrotoluene, or the like); a phenothiazine-based polymerization inhibitor (for example, phenothiazine, 2-methoxyphenothiazine, or the like); and the like.

Among these, in order for the curable composition to have further improved effects of the present invention, a phenol-based polymerization inhibitor or a free radical-based polymerization inhibitor is preferable.

The polymerization inhibitor may be mixed with other components at the time of preparing the curable composition. Alternatively, the polymerization initiator used at the time of synthesizing the aforementioned resin and the like may be mixed with other components together with the resin.

The content of the polymerization inhibitor in the curable composition is not particularly limited. In order for the curable composition to have better temporal stability and better curing properties, the content of the polymerization inhibitor with respect to the total solid content of the curable composition is preferably 0.00001% to 1% by mass.

One kind of polymerization inhibitor may be used singly, or two or more kinds of polymerization inhibitors may be used in combination. In a case where two or more kinds of polymerization inhibitors are used in combination, the total content thereof is preferably within the above range.

<Surfactant>

The curable composition may contain a surfactant. The curable composition containing a surfactant has better coating properties.

Examples of the surfactant include a fluorine-based surfactant, a nonionic surfactant, a cationic surfactant, an anionic surfactant, and a silicone-based surfactant.

For example, in a case where the curable composition contains a fluorine-based surfactant, the liquid characteristics (particularly, fluidity) of the curable composition are further improved. That is, in a case where a curable composition layer is formed on a substrate by using the curable composition containing the fluorine-based surfactant, the interfacial tension between the substrate and the curable composition is reduced, and accordingly, the wettability with respect to the substrate is improved, and the coating properties of the curable composition are improved. Therefore, even in a case where a curable composition layer having a thickness of about several micrometers is formed of a small amount of the curable composition, a curable composition layer having a more uniform thickness and small thickness unevenness can be formed.

The content of fluorine in the fluorine-based surfactant is not particularly limited, but is preferably 3% to 40% by mass, more preferably 5% to 30% by mass, and even more preferably 7% to 25% by mass. In a case where a curable composition, which contains a fluorine-based surfactant with a fluorine content of 3% to 40% by mass, is used, a curable composition layer having a more uniform thickness can be formed. As a result, the curable composition has better liquid saving properties. Furthermore, in a case where the fluorine content is within the above range, the fluorine-based surfactant is more easily dissolved in the curable composition.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, and MEGAFACE F780 (manufactured by DIC Corporation), FLUORAD FC430, FLUORAD FC431, and FLUORAD FC171 (manufactured by Sumitomo 3M Limited), SURFLON S-382, SURFLON SC-101, SURFLON SC-103, SURFLON SC-104, SURFLON SC-105, SURFLON SC-1068, SURFLON SC-381, SURFLON SC-383, SURFLON S-393, and SURFLON KH-40 (manufactured by ASAHI GLASS CO., LTD.), PF636, PF656, PF6320, PF6520, and PF7002 (manufactured by OMNOVA Solutions Inc.), and the like.

As the fluorine-based surfactant, a block polymer can also be used. For example, the compounds described in JP2011-089090A can also be used, and the content of the document is incorporated into the present specification.

The content of the surfactant in the curable composition is not particularly limited. However, the content of the surfactant with respect to the total solid content of the curable composition is preferably 0.001% to 2.0% by mass.

One kind of surfactant may be used singly, or two or more kinds of surfactants may be used in combination. In a case where two or more kinds of surfactants are used in combination, the total content thereof is preferably within the above range.

<Colorant>

The curable composition may contain a colorant. In the present specification, carbon black is not included in the colorant.

As the colorant, various known pigments (coloring pigments) and dyes (coloring dyes) can be used. Examples of the pigments include inorganic pigments and organic pigments.

In a case where the curable composition contains a colorant, the content of the colorant can be determined according to the optical characteristics of the cured film to be obtained. Furthermore, one kind of colorant may be used singly, or two or more kinds of colorants may be used in combination.

(Pigment)

The type of inorganic pigments is not particularly limited, and examples thereof include known inorganic pigments.

Examples of the inorganic pigment include carbon black, silica, zinc oxide, white lead, lithopone, titanium oxide, chromium oxide, iron oxide, precipitated barium sulfate, barite powder, red lead, red iron oxide, chromium yellow, zinc chromium (one kind of zinc chromium or two kinds of zinc chromium), ultramarine blue, Prussian blue (potassium ferric ferrocyanide), zircon grey, Praseodymium yellow, chromium titanium yellow, chromium green, peacock, Victoria green, iron blue (irrelevant to Prussian blue), vanadium zirconium blue, chromium tin pink, manganese pink, salmon pink, and the like. Examples of black inorganic pigments include a metal oxide, a metal nitride, a metal oxynitride, and the like containing at least one kind of metallic element selected from the group consisting of Co, Cr, Cu, Mn, Ru, Fe, Ni, Sn, Ti, and Ag.

As an inorganic pigment, titanium black, a metallic pigment, or the like is preferable because this pigment makes it possible to form a colored film having a high optical density even though the content of the pigment is small, and titanium black is more preferable because this pigment further improves the evaluation results of post-development lenticulation and the evaluation results of proportion of residual film that will be described later.

Examples of the metallic pigment include a metal oxide, a metal nitride, a metal oxynitride, and the like containing at least one kind of metallic element selected from the group consisting of Nb, V, Co, Cr, Cu, Mn, Ru, Fe, Ni, Sn, Ti, and Ag.

Examples of organic pigments include Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like,

C. I. Pigment Orange 2, 5, 13, 16, 17:1, 31, 34, 36, 38, 43, 46, 48, 49, 51, 52, 55, 59, 60, 61, 62, 64, 71, 73, and the like,

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (based on xanthene, Organo Ultramarine, Bluish Red), and the like;

C. I. Pigment Green 7, 10, 36, 37, 58, 59, and the like; C. I. Pigment Violet 1, 19, 23, 27, 32, 37, 42, and the like; C. I. Pigment Blue 1, 2, 15, 15:1, 15:2, 15:3, 15:4, 15:6, 16, 22, 29, 60, 64, 66, 79, 80, 87 (based on monoazo), 88 (based on methine/polymethine), and the like. One kind of pigment may be used singly, or two or more kinds of pigments may be used in combination.

(Dye)

As the dye, for example, it is possible to use the coloring agents disclosed in JP1989-090403A (JP-S64-090403A), JP1989-091102A (JP-S64-091102A), JP1989-094301A (JP-H01-094301A), JP1994-011614A (JP-H06-011614A), JP2592207B, U.S. Pat. No. 4,808,501A, US505950A, U.S. Pat. No. 5,667,920A, JP1993-333207A (JP-H05-333207A), JP1994-035183A (JP-H06-035183A), JP1994-051115A (JP-H06-051115A), JP1994-194828A (JP-H06-194828A), and the like. The contents of the above documents are incorporated into the present specification.

As dyes sorted based on the chemical structure, it is possible to use a pyrazole azo compound, a pyrromethene compound, an anilinoazo compound, a triphenylmethane compound, an anthraquinone compound, a benzylidene compound, an oxonol compound, a pyrazolotriazole azo compound, a pyridone azo compound, a cyanine compound, a phenothiazine compound, a pyrrolopyrazole azomethine compound, and the like. Furthermore, a coloring agent multimer may also be used. Examples of the coloring agent multimer include the compounds described in JP2011-213925A and JP2013-041097A. In addition, a polymerizable dye containing a polymerizable group in a molecule can also be used, and examples thereof include commercial products such as an RDW series manufactured by Wako Pure Chemical Industries, Ltd.

(Infrared Absorber)

The aforementioned colorant may further contain an infrared absorber. The infrared absorber means a component different from the inorganic particles described above.

In the present specification, the infrared absorber means a compound absorbing light having a wavelength in an infrared range (preferably at a wavelength of 650 to 1,300 nm). The infrared absorber is preferably a compound having a maximum absorption wavelength in a range of a wavelength of 675 to 900 nm.

Examples of compounds having such spectral characteristics include a pyrrolopyrrole compound, a copper compound, a cyanine compound, a phthalocyanine compound, an iminium compound, a thiol complex-based compound, a transition metal oxide-based compound, a squarylium compound, a naphthalocyanine compound, a quatenylene compound, a dithiol metal complex-based compound, a croconium compound, and the like.

As the colorant having the spectral characteristics described above, it is possible to use the compound described in paragraphs “0004” to “0016” in JP1995-164729A (JP-H07-164729A), the compound described in paragraphs “0027” to “0062” in JP2002-146254A, and the near-infrared absorption particles described in paragraphs “0034” to “0067” in JP2011-164583A that are formed of crystallites of an oxide containing Cu and/or P and have a number-average aggregated particle diameter of 5 to 200 nm. The contents of the paragraphs are incorporated into the present specification.

As the compound having a maximum absorption wavelength in a range of a wavelength of 675 to 900 nm, at least one kind of compound selected from the group consisting of a cyanine compound, a pyrrolopyrrole compound, a squarylium compound, a phthalocyanine compound, and a naphthalocyanine compound is preferable.

Furthermore, the infrared absorber is preferably a compound which dissolves in an amount equal to or greater than 1% by mass in water at 25° C., and more preferably a compound which dissolves in an amount equal to or greater than 10% by mass in water at 25° C. In a case where such a compound is used, solvent resistance becomes excellent.

Regarding the pyrrolopyrrole compound, paragraphs “0049” to “0062” in JP2010-222557A can be referred to, and the contents of the paragraphs are incorporated into the present specification. Regarding the cyanine compound and the squarylium compound, paragraphs “0022” to “0063” in WO2014/088063A, paragraphs “0053” to “0118” in WO2014/030628A, paragraphs “0028” to “0074” in JP2014-059550A, paragraphs “0013” to “0091” in WO2012/169447A, paragraphs “0019” to “0033” in JP2015-176046A, paragraphs “0053” to “0099” in JP2014-063144A, paragraphs “0085” to “0150” in JP2014-052431A, paragraphs “0076” to “0124” in JP2014-044301A, paragraphs “0045” to “0078” in JP2012-008532A, paragraphs “0027” to “0067” in JP2015-172102A, paragraphs “0029” to “0067” in JP2015-172004A, paragraphs “0029” to “0085” in JP2015-040895A, paragraphs “0022” to “0036” in JP2014-126642A, paragraphs “0011” to “0017” in JP2014-148567A, paragraphs “0010” to “0025” in JP2015-157893A, paragraphs “0013” to “0026” in JP2014-095007A, paragraphs “0013” to “0047” in JP2014-080487A, paragraphs “0007” to “0028” in JP2013-227403A, and the like can be referred to, and the contents of the paragraphs are incorporated into the present specification.

The content of the colorant in the curable composition is not particularly limited, but is preferably 0.0001% to 70% by mass with respect to the total solid content of the curable composition in general. One kind of colorant may be used singly, or two or more kinds of colorants may be used in combination. In a case where two or more kinds of colorants are used in combination, the total content thereof is preferably within the above range.

<Ultraviolet Absorber>

The curable composition may contain an ultraviolet absorber. In a case where the curable composition contains an ultraviolet absorber, a cured film obtained from the composition has a better pattern shape (finer pattern shape).

As the ultraviolet absorber, it is possible to use ultraviolet absorbers based on salicylate, benzophenone, benzotriazole, substituted acrylonitrile, triazine, and the like. For example, as the ultraviolet absorber, the compounds described in paragraphs “0137” to “0142” in JP2012-068418A (paragraphs “0251” to “0254” in US2012/0068292A corresponding to JP2012-068418A) can be used, and the contents of the paragraphs can be adopted and incorporated into the present specification.

In addition, as the ultraviolet absorber, a diethylamino-phenylsulfonyl-based ultraviolet absorber (manufactured by DAITO CHEMICAL CO., LTD., trade name: UV-503) and the like can also be used.

As the ultraviolet absorber, the compounds described in paragraphs “0134” to “0148” in JP2012-032556A can also be used, and the contents of the paragraphs are incorporated into the present specification.

The content of the ultraviolet absorber in the curable composition is not particularly limited. The content of the ultraviolet absorber with respect to the total solid content of the curable composition is preferably 0.001% to 15% by mass, more preferably 0.01% to 10% by mass, and even more preferably 0.1% to 5% by mass.

<Silane Coupling Agent>

The curable composition may contain a silane coupling agent.

In the present specification, the silane coupling agent means a compound containing the following hydrolyzable group and other functional groups in a molecule. The hydrolyzable group refers to a substituent which is directly bonded to a silicon atom and can form a siloxane bond by a hydrolysis reaction and/or a condensation reaction. Examples of the hydrolyzable group include a halogen atom, an alkoxy group, an acyloxy group, and an alkenyloxy group directly bonded to a silicon atom. In a case where the hydrolyzable group contains carbon atoms, the number of carbon atoms is preferably equal to or smaller than 6, and more preferably equal to or smaller than 4. Particularly, an alkoxy group having 4 or less carbon atoms or an alkenyloxy group having 4 or less carbon atoms is preferable.

It is preferable that the silane coupling agent contains none of the silicon atoms and fluorine atoms other than the silicon atom bonded to the hydrolyzable group. In a case where a cured film is formed on a substrate by using the curable composition containing the silane coupling agent, the cured film exhibits higher adhesiveness with respect to the substrate.

In the curable composition, the content of the silane coupling agent with respect to the total solid content in the curable composition is preferably 0.1% to 10% by mass, more preferably 0.5% to 8% by mass, and even more preferably 1.0% to 6% by mass.

One kind of silane coupling agent may be used singly, or two or more kinds of silane coupling agents may be used in combination. In a case where two or more kinds of silane coupling agents are used in combination, the total content thereof is preferably within the above range.

<Solvent>

It is preferable that the curable composition contains a solvent. As the solvent, known solvents can be used without particular limitation.

The content of the solvent in the curable composition is not particularly limited. Generally, the content of the solvent is preferably adjusted such that the concentration of solid contents of the curable composition becomes 10% to 90% by mass, and more preferably adjusted such that the concentration of solid contents of the curable composition becomes 10% to 50% by mass.

One kind of solvent may be used singly, or two or more kinds of solvents may be used in combination. In a case where two or more kinds of solvents are used in combination, it is preferable that the content thereof is adjusted such that the total solid content of the curable composition falls into the above range.

Examples of the solvent include water and an organic solvent.

Examples of the organic solvent include acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetyl acetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxyethoxy ethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, γ-butyrolactone, butyl acetate, methyl lactate, N-methyl-2-pyrrolidone, ethyl lactate, and the like.

Among these, in view of further improving the evaluation result of in-plane uniformity which will be described later, a solvent having a boiling point equal to or higher than 170° C. (preferably an organic solvent) is preferable. The upper limit of the boiling point of the solvent is not particularly limited. However, in view of handleability, the upper limit of the boiling point is preferably equal to or lower than 300° C., and more preferably equal to or lower than 250° C.

<Manufacturing Method of Curable Composition>

The curable composition can be prepared by mixing together the aforementioned components by known mixing methods (for example, mixing methods using a stirrer, a homogenizer, a high-pressure emulsification device, a wet-type pulverizer, a wet-type disperser, and the like). At the time of preparing the curable composition, the components may be mixed together at once. Alternatively, each of the components may be dissolved or dispersed in a solvent, and then sequentially mixed together. The order of components mixed in and the operation conditions are not particularly limited.

For the purpose of removing foreign substances, reducing defects, and the like, it is preferable that the curable composition is filtered through a filter. As the filter, known filters can be used without particular limitation.

The material of the filter is not particularly limited. For example, the filter may be formed of a fluororesin such as polytetrafluoroethylene (PTFE), a polyamide-based resin such as nylon, and a polyolefin-based resin (including a high-density polyolefin-based resin and an ultra-high-molecular-weight polyolefin-based resin) such as polyethylene or polypropylene (PP). Among these, a filter formed of polypropylene (including high-density polypropylene) or nylon is preferable.

The pore size of the filter is not particularly limited. Generally, the pore size is preferably 0.1 to 7.0 μm, more preferably 0.2 to 2.5 μm, even more preferably 0.2 to 1.5 μm, and particularly preferably 0.3 to 0.7 μm.

At the time of using filters, different filters may be used in combination. At this time, filtering performed using a first filter may be carried out only once or twice or more. In a case where filtering is performed twice or more by using a combination of different filters, the pore size of the filter used in the second filtering is preferably the same as or larger than the pore size of the filter used in the first filtering. In addition, filters formed of the same material and having different pore sizes may be combined. Regarding the pore size, the nominal pore size of the filter manufacturer can be referred to.

Examples of commercial filters include filters from Pall Corporation Japan, Advantac Toyo Kaisha, Ltd., Nihon Entegris K.K. (former MICRONIX JAPAN CO., LTD.), KITZ MICRO FILTER CORPORATION, and the like.

As a second filter, a filter formed of the same material as the first filter described above and the like can be used. The pore size of the second filter is not particularly limited. Generally, the pore size of the second filter is preferably 0.2 to 10.0 μm, more preferably 0.2 to 7.0 μm, and even more preferably 0.3 to 6.0 μm.

It is preferable that the curable composition substantially does not contain impurities such as a metal (particles and ions), a metal salt containing halogen, an acid, and an alkali. In the present specification, “substantially does not contain” means that the impurities are undetectable by the following measurement method.

The content of the impurity contained in the curable composition, the aforementioned components, the aforementioned filter, and the like is not particularly limited. The content of the impurity with respect to the total mass of each of the curable composition, the aforementioned component, the aforementioned filter, and the like is preferably equal to or smaller than 1 mass ppm, more preferably equal to or smaller than 1 mass ppb, even more preferably equal to or smaller than 100 mass ppt, and particularly preferably equal to or smaller than 10 mass ppt. It is most preferable that the curable composition, the aforementioned components, the aforementioned filter, and the like substantially do not contain the impurity.

The content of the impurity can be measured using an inductively coupled plasma mass spectrometer (manufactured by Yokogawa Analytical Systems, Inc., Agilent 7500cs model).

ppm represents parts per million, ppb represents parts per billion, and ppt represents parts per trillion.

<Cured Film and Manufacturing Method of Cured Film>

The cured film according to an embodiment of the present invention is a cured film obtained by curing the aforementioned curable composition. The thickness of the cured film is not particularly limited, but is preferably 0.2 to 7 μm and more preferably 0.4 to 5 μm in general.

The aforementioned thickness is an average thickness which is a value determined by measuring the thickness of the cured film at any 5 or more sites and calculating an arithmetic mean thereof.

The manufacturing method of the cured film is not particularly limited, and examples thereof include a method of coating a substrate with the curable composition so as to form a coating film and performing a curing treatment on the coating film so as to manufacturing a cured film.

The method of the curing treatment is not particularly limited, and examples thereof include a photocuring treatment and a thermal curing treatment. In view of easily forming a pattern, a photocuring treatment (particularly, a curing treatment performed by irradiation with actinic rays or radiation) is preferable.

The cured film according to the embodiment of the present invention is a cured film obtained by curing a curable composition layer formed using the curable composition.

The manufacturing method of the cured film is not particularly limited, but preferably includes the following steps.
Curable composition layer forming step
Exposure step
Development step

Hereinafter, each of the steps will be described.

(Curable Composition Layer Forming Step)

The curable composition layer forming step is a step of forming a curable composition layer by using the curable composition. Examples of the step of forming a curable composition layer by using the curable composition include a step of coating a substrate with the curable composition so as to form a curable composition layer.

The type of the substrate is not particularly limited. In a case where the substrate is used in a solid-state imaging element, examples of the substrate include a silicon substrate. In a case where the substrate is used in a color filter (including a color filter for a solid-state imaging element), examples of the substrate include a glass substrate (glass wafer), and the like.

Examples of the method for coating a substrate with the curable composition include various coating methods such as a spin coating method, a slit coating method, an ink jet coating method, a spray coating method, a spin coating method, a cast coating method, a roll coating method, and a screen printing method.

The curable composition with which the substrate is coated is generally formed into a curable composition layer by being dried under the condition of a temperature of 70° C. to 150° C. for about 1 to 4 minutes.

(Exposure Step)

In the exposure step, the curable composition layer formed in the curable composition layer forming step is subjected to exposure by being irradiated with actinic rays or radiation through a photomask comprising a pattern-like opening portion such that only the curable composition layer irradiated with light is cured.

It is preferable to perform exposure by the irradiation of radiation. It is preferable to use ultraviolet rays such as g-line, h-line, and i-line. As a light source, a high-pressure mercury lamp is preferable. The irradiation intensity is not particularly limited, but is preferably 5 to 1,500 mJ/cm² and more preferably 10 to 1,000 mJ/cm².

(Development Step)

After the exposure step, a development treatment (development step) is performed such that a portion not being exposed to light in the exposure step is eluted in a developer. In this way, only a portion cured by light remains on the substrate.

The developer is not particularly limited, and examples thereof include an aqueous alkaline solution such as an inorganic alkaline developer and an organic alkaline developer. Among these, an organic alkaline developer is preferable. The development conditions are not particularly limited. The development temperature is generally preferably 20° C. to 40° C., and the development time is generally preferably 20 to 180 seconds.

Examples of alkaline compounds to be incorporated into inorganic alkaline developers include sodium hydroxide, potassium hydroxide, sodium carbonate, sodium hydrogen carbonate, sodium silicate, sodium metasilicate, and the like.

The content of the alkaline compound in the inorganic alkaline developers is not particularly limited. Generally, the content of the alkaline compound with respect to the total mass of the inorganic alkaline developer is preferably 0.001% to 10% by mass, and more preferably 0.005% to 0.5% by mass.

Examples of alkaline compounds incorporated into the organic alkaline developer include ammonia, ethylamine, diethylamine, dimethylethanolamine, tetramethylammonium hydroxide, tetraethylammonium hydroxide, tetrapropyl ammonium hydroxide, tetrabutylammonium hydroxide, benzyltrimethylammonium hydroxide, choline, pyrrole, piperidine, 1,8-diazabicyclo-[5,4,0]-7-undecen, and the like.

The content of the alkaline compound in the organic alkaline developer is not particularly limited. Generally, the content of the alkaline compound with respect to the total mass of the organic alkaline developer is preferably 0.001% to 10% by mass, and more preferably 0.005% to 0.5% by mass.

The aqueous alkaline solution may contain a water-soluble organic solvent such as methanol or ethanol. Furthermore, the aqueous alkaline solution may contain a surfactant.

In a case where the aqueous alkaline solution described above is used as a developer, it is preferable to rinse the cured film with pure water after development.

The manufacturing method of a cured film may further include other steps.

Those other steps are not particularly limited, and can be appropriately selected according to the purpose.

Examples of those other steps include a substrate surface treatment step, a pre-baking step, a post-baking step, a post-exposure step (step of performing exposure again after exposure and development), and the like.

The heating temperature in the pre-baking step and the post-baking step is preferably 80° C. to 300° C. The heating time in the pre-baking step and the post-baking step is preferably 30 to 300 seconds.

In the post-exposure step, it is preferable to perform exposure by the irradiation of radiation. It is preferable to use ultraviolet rays such as g-line, h-line, and i-line. As a light source, a high-pressure mercury lamp is preferable. The irradiation intensity is not particularly limited, but is preferably 5 to 1,500 mJ/cm² and more preferably 10 to 1,000 mJ/cm².

The cured film is suitable for a light blocking member, a light blocking film, an antireflection member, and an antireflection film of optical filters and modules used in portable instruments such as a personal computer, a tablet PC, a mobile phone, a smartphone, and a digital camera; office automation (OA) instruments such as a printer composite machine and a scanner; industrial instruments such as monitoring camera, a barcode reader, an automated teller machine (ATM), a high-speed camera, an instrument having a personal authentication function exploiting face image recognition; camera instruments for automobile use; medical camera instruments such as an endoscope, a capsule endoscope, and a catheter; a biosensor, a military reconnaissance camera, a camera for a three-dimensional map, a camera for observing weather and sea, a camera for land resource investigation, space instruments such as an exploration camera for the astronomy of the universe and a deep space target; and the like.

“Light blocking” using the cured film may include the attenuation of light by which light is attenuated while passing through the cured film.

The cured film can also be used in a micro light emitting diode (LED), a micro organic light emitting diode (OLED), and the like. The cured film is suitable for an optical filter and an optical film used in the micro LED and the micro OLED and for a member to which a light blocking function or an antireflection function is to be imparted.

Examples of the micro LED and the micro OLED include those described in JP2015-500562A and JP2014-533890A.

The cured film is suitable for optical filter and an optical film used in a quantum dot display. Furthermore, the cured film is suitable as a member to which a light blocking function or an antireflection function is to be imparted.

Examples of the quantum dot display include those described in US2013/0335677A, US2014/0036536A, US2014/0036203A, and US2014/0035960A.

The cured film is also preferably used in a light blocking member and/or a light blocking film of a headlight unit used in headlights for vehicles such as automobiles. Furthermore, the cured film is preferably used in an antireflection member, an antireflection film, and the like.

<Solid-State Imaging Device and Solid-State Imaging Element>

The solid-state imaging device and the solid-state imaging element according to an embodiment of the present invention include the cured film described above. The aspect in which the solid-state imaging element includes the cured film is not particularly limited. For example, a constitution may be adopted in which a plurality of photodiodes and light-receiving elements formed of polysilicon or the like constituting a light-receiving area of a solid-state imaging element (a Charge Coupled Device (CCD) image sensor, a Complementary Metal Oxide Semiconductor (CMOS) image sensor, or the like) are provided on a substrate, and solid-state imaging element comprises the cured film on a surface side of a support on which the light-receiving elements are formed (for example, a portion other than light-receiving portions and/or pixels for adjusting color, and the like) or on a side opposite to the surface on which the light-receiving elements are formed.

The solid-state imaging device includes the aforementioned solid-state imaging element.

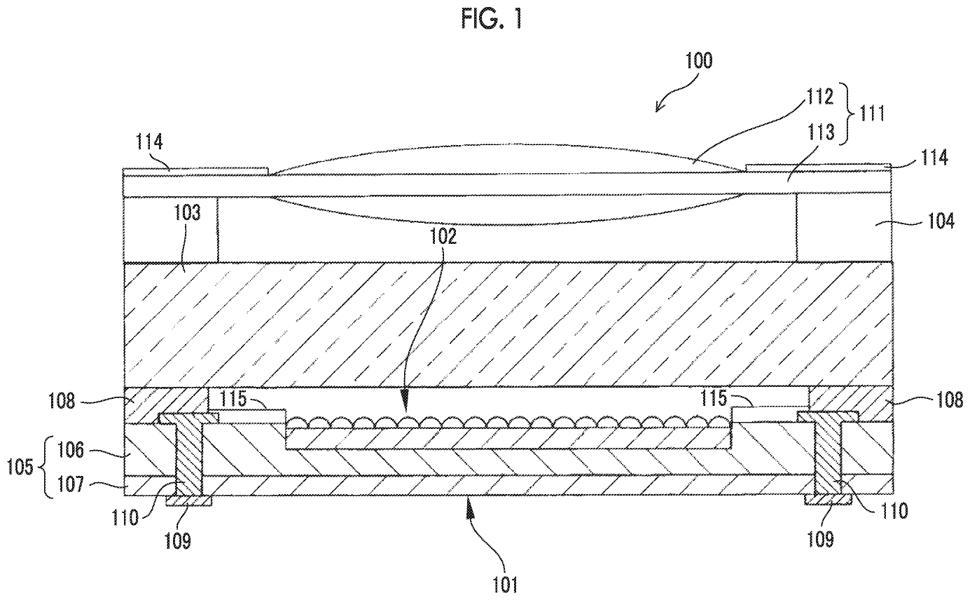

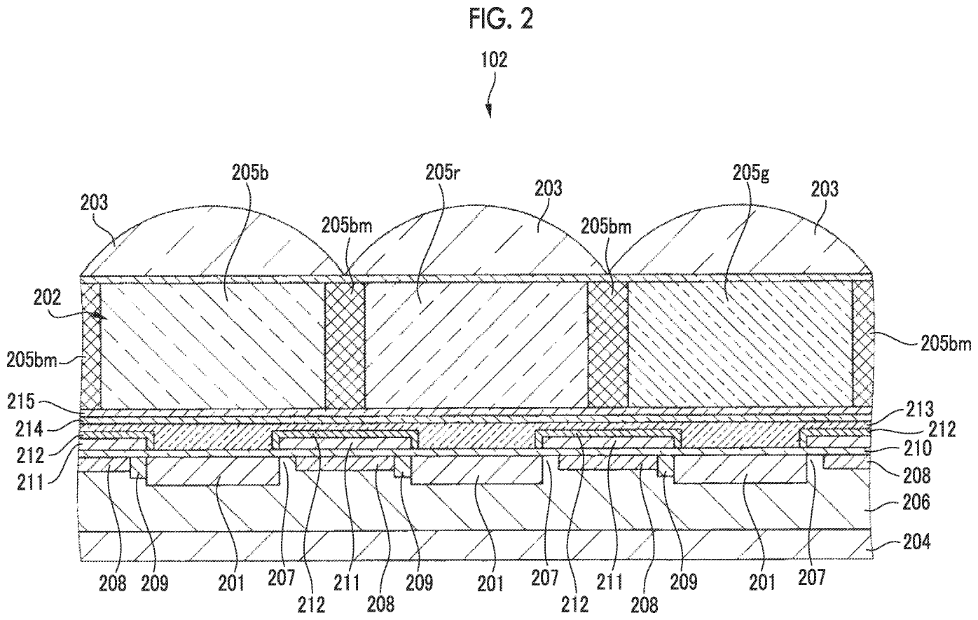

Examples of the constitutions of the solid-state imaging device and the solid-state imaging element will be described with reference to FIG. 1 and FIG. 2. In FIG. 1 and FIG. 2, in order that each portion is clearly seen, some portions are magnified in disregard of a thickness ratio and/or a width ratio between the portions.

As shown in FIG. 1, a solid-state imaging device 100 comprises a rectangular solid-state imaging element 101 and a transparent cover glass 103 which is held above the solid-state imaging element 101 and seals the solid-state imaging element 101. Furthermore, on the cover glass 103, a lens layer 111 is superposed through a spacer 104. The lens layer 111 is constituted with a support 113 and a lens material 112. The lens layer 111 may be constituted with the support 113 and the lens material 112 that are integrally formed. In a case where stray light comes into the peripheral region of the lens layer 111, due to the diffusion of light, a light condensing effect of the lens material 112 is weakened. Accordingly, the light reaching an imaging portion 102 is reduced, and noise occurs due to the stray light. Therefore, a light blocking film 114 is provided in the peripheral region of the lens layer 111 such that light is blocked. The cured film according to the embodiment of the present invention can also be used as the light blocking film 114.

The solid-state imaging element 101 performs photoelectric conversion on an optical image formed by the imaging portion 102, which becomes a light-receiving surface of the solid-state imaging element 101, and outputs the converted optical image as an image signal. The solid-state imaging element 101 comprises a laminated substrate 105 obtained by laminating two sheets of substrates. The laminated substrate 105 is formed of a chip substrate 106 and a circuit substrate 107 that are rectangular substrates having the same size. The circuit substrate 107 is laminated on the rear surface of the chip substrate 106.

As the material of the substrate used as the chip substrate 106, known materials can be used without particular limitation.

The imaging portion 102 is provided in the central portion of the surface of the chip substrate 106. In a case where stray light comes into the peripheral region of the imaging portion 102, a dark current (noise) occurs from the circuit in the peripheral region. Therefore, the peripheral region is provided with a light blocking film 115 such that light is blocked. The cured film according to the embodiment of the present invention can also be used as the light blocking film 115.

A plurality of electrode pads 108 are provided at the edge of the surface of the chip substrate 106. The electrode pads 108 are electrically connected to the imaging portion 102 through a signal line (a bonding wire can also be used) not shown in the drawing that is provided on the surface of the chip substrate 106.

On the rear surface of the circuit substrate 107, external connection terminals 109 are provided approximately in positions below the electrode pads 108. The external connection terminals 109 are connected to the electrode pads 108 through a penetration electrode 110 vertically penetrating the laminated substrate 105. Furthermore, the external connection terminals 109 are connected to a control circuit controlling the driving of the solid-state imaging element 101, an image processing circuit performing image processing on an imaging signal output from the solid-state imaging element 101, and the like through wiring not shown in the drawing.

As shown in FIG. 2, the imaging portion 102 is constituted with the portions provided on a substrate 204 such as a light-receiving element 201, a color filter 202, and a microlens 203. The color filter 202 has a blue pixel 205b, a red pixel 205r, a green pixel 205g, and a black matrix 205bm. The cured film according to the embodiment of the present invention can also be used as the black matrix 205bm.

As the material of the substrate 204, the same material as that of the chip substrate 106 can be used. On the surface layer of the substrate 204, a p-well layer 206 is formed. In the p-well layer 206, the light-receiving elements 201, which are formed of an n-type layer and generate and accumulate signal charges by photoelectric conversion, are arranged in the form of square grids.

On one lateral side of each light-receiving element 201, through a reading gate portion 207 on the surface layer of the p-well layer 206, a vertical electric charge transfer path 208 formed of an n-type layer is formed. Furthermore, on the other lateral side of each light-receiving element 201, through an element separation region 209 formed of a p-type layer, a vertical electric charge transfer path 208 belonging to the adjacent pixel is formed. The reading gate portion 207 is a channel region for the signal charges accumulated in the light-receiving element 201 to be read toward the vertical electric charge transfer path 208.

On the surface of the substrate 204, a gate insulating film 210 formed of an oxide-nitride-oxide (ONO) film is formed. On the gate insulating film 210, vertical electric charge transfer electrodes 211 formed of polysilicon or amorphous silicon are formed to cover the portions which are approximately immediately above the vertical electric charge transfer path 208, the reading gate portion 207, and the element separation region 209. The vertical electric charge transfer electrodes 211 function as driving electrodes for driving the vertical electric charge transfer path 208 and performing charge transfer and as reading electrodes for driving the reading gate portion 207 and reading out signal charges. The signal charges are transferred to a horizontal electric charge transfer path and an output portion (floating diffusion amplifier), which are not shown in the drawing, in this order from the vertical electric charge transfer path 208 and then output as voltage signals.

On each of the vertical electric charge transfer electrodes 211, a light blocking film 212 is formed to cover the surface of the electrode. The light blocking film 212 has an opening portion in a position immediately above the light-receiving element 201 and shields a region other than the opening portion from light. The cured film according to the embodiment of the present invention can also be used as the light blocking film 212.

On the light blocking film 212, a transparent interlayer is provided which is formed of an insulating film 213 formed of borophosphosilicate glass (BPSG), an insulating film (passivation film) 214 formed of P—SiN, and a planarization film 215 formed of a transparent resin or the like. The color filter 202 is formed on the interlayer.

In addition, examples of methods for applying the cured film to a solid-state imaging element (solid-state imaging device) include a method of using the cured film (light blocking film) as a light attenuation film. For example, there is a method of disposing a light attenuation film such that some light rays are incident on a light-receiving element after passing through the light attenuation film, and by this method, a dynamic range of the solid-state imaging element is improved.

<Black Matrix>

The black matrix includes the cured film according to the embodiment of the present invention. The black matrix is incorporated into a color filter, a solid-state imaging element, and a liquid crystal display device in some cases.

Examples of the black matrix include those described above; a black rim provided in the peripheral portion of a display device such as a liquid crystal display device; a grid-like and/or a stripe-like black portion between pixels of red, blue, and green; a dot-like and/or a linear black pattern for shielding a thin film transistor (TFT) from light; and the like. The definition of the black matrix is described in, for example, Yasuhira Kanno, “Glossary of Liquid Crystal display Manufacturing Device”, 2^{nd} edition, NIKKAN KOGYO SHIMBUN, LTD., 1996, p. 64.

In order to improve the display contrast and to prevent image quality deterioration resulting from current leak of light in the case of an active matrix driving-type liquid crystal display device using a thin film transistor (TFT), it is preferable that the black matrix has high light blocking properties (it is preferable that the optical density OD is higher than 3).

The manufacturing method of the black matrix is not particularly limited, and the black matrix can be manufactured by the same method as the manufacturing method of the cured film described above. Specifically, by coating a substrate with the curable composition so as to form a curable composition layer and performing exposure and development, a pattern-like cured film (black matrix) can be manufactured. The film thickness of the cured film used as the black matrix is preferably 0.1 to 4.0 μm.

The material of the substrate is not particularly limited, but it is preferable that the material has a transmittance equal to or higher than 80% for visible light (wavelength: 400 to 800 nm). Specifically, examples of such a material include glass such as soda lime glass, alkali-free glass, quartz glass, and borosilicate glass; plastic such as a polyester-based resin and a polyolefin-based resin; and the like. From the viewpoint of chemical resistance and heat resistance, alkali-free glass, quartz glass, or the like is preferable.

<Color Filter>

The color filter according to an embodiment of the present invention includes a cured film.

The aspect in which the color filter includes the cured film is not particularly limited, and examples thereof include a color filter comprising a substrate and the aforementioned black matrix. That is, examples of the color filter include a color filter comprising colored pixels of red, green, and blue formed on the opening portion of the black matrix formed on a substrate.

The color filter including a black matrix (cured film) can be manufactured, for example, by the following method.

First, on an opening portion of a pattern-like black matrix formed on a substrate, a coating film of a resin composition (resin composition layer) containing pigments corresponding to the colored pixels of the color filter is formed. Then, the resin composition layer is subjected to exposure through a photo mask having a pattern corresponding to the opening portion of the black matrix. Thereafter, an unexposed portion is removed by a development treatment and then performing baking. In this way, colored pixels can be formed in the opening portion of the black matrix. In a case where the series of operations are performed using, for example, a resin composition for each color containing red, green, and blue pigments, a color filter having red, green, and blue pixels can be manufactured.

<Image Display Device>

The image display device according to an embodiment of the present invention includes a cured film. The aspect in which the image display device (typical examples thereof include a liquid crystal display device, hereinafter, the liquid crystal display device will be described) includes the cured film is not particularly limited, and examples thereof include an aspect in which the image display device includes a color filter including the black matrix (cured film) described above.

Examples of the liquid crystal display device according to the present embodiment include an aspect in which the liquid crystal display device comprises a pair of substrates disposed to face each other and a liquid crystal compound sealed into the space between the substrates. The substrates are as described above as the substrate for a black matrix.

Examples of a specific aspect of the liquid crystal display device include a laminate having polarizing plate/substrate/color filter/transparent electrode layer/alignment film/liquid crystal layer/alignment film/transparent electrode layer/Thin Film Transistor (TFT) element/substrate/polarizing plate/backlight unit in this order from the user's side.

The liquid crystal display device is not limited to the above, and examples thereof include the liquid crystal display devices described in “Electronic display device (Akio Sasaki, Kogyo Chosakai Publishing Co., Ltd., 1990)” and “Display Device (Sumiaki Ibuki, Sangyo Tosho Publishing Co., Ltd., 1989)” and the liquid crystal display device described in “Next-Generation Liquid Crystal Display Technology (Tatsuo Uchida, Kogyo Chosakai Publishing Co., Ltd., 1994)”.

### Examples

Hereinafter, the present invention will be more specifically described based on examples. The materials, the amount of the materials used, the proportion of the materials, the treatment content, the treatment procedure, and the like shown in the following examples can be appropriately modified as long as the gist of the present invention is maintained. Accordingly, the scope of the present invention is not limited to the following examples.

First, the components to be incorporated into the curable composition will be described below.

<Manufacturing Example 1: Preparation of Carbon Black Dispersion Composition (C-1)>

By a general oil furnace method, carbon black was manufactured. Here, as raw material oil, ethylene bottom oil containing small amounts of Na, Ca, and S was combusted using a gas fuel. Furthermore, as water for stopping the reaction, pure water treated with an ion exchange resin was used.

By using a homomixer, the obtained carbon black (540 g) and pure water (14,500 g) were stirred together at 5,000 to 6,000 rpm for 30 minutes, thereby obtaining a slurry. The slurry was moved to a container with a screw-type stirrer, and while the slurry was being mixed at about 1,000 rpm, toluene (600 g), in which an epoxy resin “EPIKOTE 828” (manufactured by Japan Epoxy Resin Co., Ltd.) (60 g) was dissolved, was added to the slurry little by little. After about 15 minutes, the entirety of carbon black dispersed in water was moved to the side of toluene, thereby obtaining grains having a size of about 1 mm.

Then, the grains were drained using a 60 mesh wire net, and the separated grains were put into a vacuum drier and dried for 7 hours at 70° C. such that toluene and water were removed. The amount of resin coating the obtained coated carbon black was 10% by mass with respect to the total amount of the carbon black and the resin.

Disperbyk-167 (manufactured by BYK Additives & Instruments) (4.5 parts by mass) as a dispersant and S12000 (manufactured by Lubrizol Japan Limited.) (1 part by mass) as a pigment derivative were added to the obtained coated carbon black (20 parts by mass), and propylene glycol monomethyl ether acetate (PGMEA) was added thereto such that the concentration of solid contents became 35% by mass.

The obtained dispersion was premixed by being thoroughly stirred using a stirrer. In addition, by using Ultra Apex Mill UAM015 manufactured by KOTOBUKI KOGYO CO., LTD., a dispersion treatment was performed on the dispersion under the following conditions, thereby obtaining a dispersion composition. After dispersion ended, beads were separated from the dispersion liquid by a filter, thereby preparing a carbon black dispersion composition (C-1).

(Dispersion Conditions)
Bead size: ϕ0.05 mm
Bead filling rate: 75% by volume
Circumferential speed of mill: 8 msec
Amount of mixed solution subjected to dispersion treatment: 500 g
Circulation flow rate (pump feeding amount): 13 kg/hour
Treatment solution temperature: 25° C. to 30° C.
Coolant: tap water
Inner volume of circular path of beads mill: 0.15 L
Number of times of pass: 90 passes

<Preparation of Carbon Black Dispersion Composition (C-2)>

EFKA 4046 (manufactured by BASF SE) (5 parts by mass) as a dispersant and S12000 (manufactured by Lubrizol Japan Limited.) (1 part by mass) as a pigment derivative were added to carbon black for color (“MA-8” manufactured by Mitsubishi Chemical Corporation, average particle diameter: 24 μm, dibutyl phthalate (DBP) oil absorption amount: 58 ml/100 g) (25 parts by mass), and propylene glycol monomethyl ether acetate (PGMEA) was further added thereto such that the concentration of solid contents became 30% by mass. The total mass of the dispersion liquid was 181 g. The obtained dispersion was premixed by being thoroughly stirred using a stirrer. In addition, by using Ultra Apex Mill UAM015 manufactured by KOTOBUKI KOGYO CO., LTD., a dispersion treatment was performed on the dispersion under the following conditions, thereby obtaining a dispersion composition. After dispersion ended, beads were separated from the dispersion liquid by a filter, thereby preparing a carbon black dispersion composition (C-2).

(Dispersion Conditions)
Bead size: ϕ0.05 mm
Bead filling rate: 75% by volume
Circumferential speed of mill: 8 msec
Amount of mixed solution subjected to dispersion treatment: 500 g
Circulation flow rate (pump feeding amount): 13 kg/hour
Treatment solution temperature: 25° C. to 30° C.
Coolant: tap water
Inner volume of circular path of beads mill: 0.15 L
Number of times of passes: 90 passes

<Preparation of Carbon Black Dispersion Composition (C-3)>

An alkali-soluble resin (b-1) (4.5 parts by mass) which will be described later and S12000 (manufactured by Lubrizol Japan Limited.) (1 part by mass) as a pigment derivative were added to the coated carbon black (20 parts by mass) prepared in <Preparation of carbon black dispersion composition (C-3)> described above, and propylene glycol monomethyl ether acetate (PGMEA) was added thereto such that the concentration of solid contents became 35% by mass.

The obtained dispersion was premixed by being thoroughly stirred using a stirrer. In addition, by using Ultra Apex Mill UAM015 manufactured by KOTOBUKI KOGYO CO., LTD., a dispersion treatment was performed on the dispersion under the following conditions, thereby obtaining a dispersion composition. After dispersion ended, beads were separated from the dispersion liquid by a filter, thereby preparing a carbon black dispersion composition (C-3).
(Dispersion conditions)
Bead size: ϕ0.05 mm
Bead filling rate: 75% by volume
Circumferential speed of mill: 8 msec
Amount of mixed solution subjected to dispersion treatment: 500 g
Circulation flow rate (pump feeding amount): 13 kg/hour
Treatment solution temperature: 25° C. to 30° C.
Coolant: tap water
Inner volume of circular path of beads mill: 0.15 L
Number of times of passes: 90 passes

<Synthesis of Specific Resin 1>

A specific resin 1 was obtained with reference to the manufacturing method described in paragraphs “0338” to “0340” in JP2010-106268A.

In the formula representing the specific resin 1, x was 90% by mass, y was 0% by mass, and z was 10% by mass. Furthermore, the specific resin 1 had a weight-average molecular weight of 40,000 and an acid value of 100 mgKOH/g, and the number of atoms (except for hydrogen atoms) constituting the graft chain thereof was 117.

Specific Resin 1

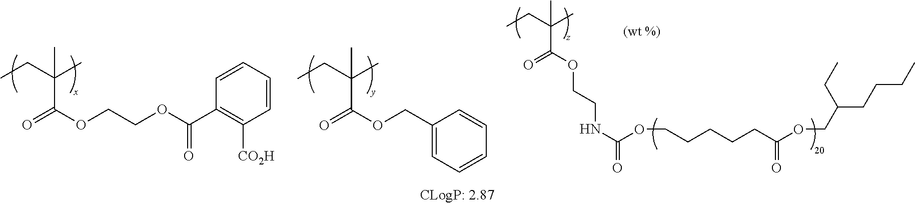

<Preparation of Titanium Black Dispersion Composition (T-1)>

Titanium oxide MT-150A (trade name: manufactured by TAYCA, 100 g) having an average particle diameter of 15 nm, 25 g of silica particles AEROPERL (registered trademark) 300/30 (manufactured by Evonik Industries AG) having a BET surface area of 300 m²/g, and 100 g of a dispersant Disperbyk 190 (trade name: manufactured by BYK Additives & Instruments) were weighed and added to 71 g of electrically deionized water. Then, by using MAZERSTAR KK-400W manufactured by KURABO INDUSTRIES LTD., the mixture was treated for 20 minutes at a revolution speed of 1,360 rpm and a rotation speed of 1,047 rpm, thereby obtaining an aqueous solution of a mixture. A quartz container was filled with the aqueous solution of the mixture, and heated to 920° C. in an oxygen atmosphere by using a small rotary kiln (manufactured by MOTOYAMA ENG. WORKS, LTD.). Thereafter, by purging the inner atmosphere of the small rotary kiln by using nitrogen and allowing ammonia gas to flow in the small rotary kiln for 5 hours at 100 mL/min at the same temperature, a nitriding reduction treatment was performed. After the nitriding reduction treatment ended, the collected powder was ground using a mortar, thereby obtaining powder-like titanium black A-1 containing Si atoms [substance to be dispersed containing titanium black particles and Si atoms, specific surface area: 73 m²/g].

The specific resin 1 (5.5 parts by mass) as a dispersant was added to the titanium black A-1 (20 parts by mass) prepared as above, and propylene glycol monomethyl ether acetate (PGMEA) was added thereto such that the concentration of solid contents became 35% by mass.

The obtained dispersion was premixed by being thoroughly stirred using a stirrer. In addition, by using Ultra Apex Mill UAM015 manufactured by KOTOBUKI KOGYO CO., LTD., a dispersion treatment was performed on the dispersion under the following conditions, thereby obtaining a dispersion composition. After dispersion ended, beads were separated from the dispersion liquid by a filter, thereby preparing a titanium black dispersion composition (T-1).

(Dispersion Conditions)
Bead size: ϕ0.05 mm
Bead filling rate: 75% by volume
Circumferential speed of mill: 8 msec
Amount of mixed solution subjected to dispersion treatment: 500 g
Circulation flow rate (pump feeding amount): 13 kg/hour
Treatment solution temperature: 25° C. to 30° C.
Coolant: tap water
Inner volume of circular path of beads mill: 0.15 L
Number of times of passes: 90 passes

<Photopolymerizable Monomer>

(M-1): (KAYARAD DPCA-20: manufactured by Nippon Kayaku Co., Ltd.: compound represented by the following structure: a=2, b=4)

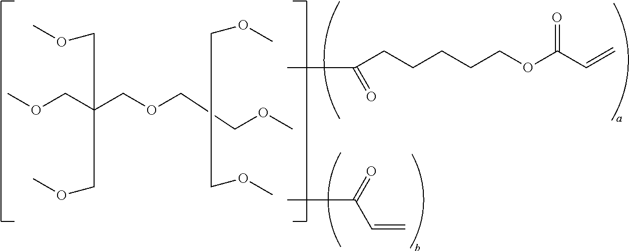

(M-2): (KAYARAD DPCA-30: manufactured by Nippon Kayaku Co., Ltd.: compound represented by the above structure: a=3, b=3)

(M-3): (KAYARAD DPCA-60: manufactured by Nippon Kayaku Co., Ltd.: compound represented by the above structure: a=6, b=0)

(M-4): (KAYARAD DPHA: manufactured by Nippon Kayaku Co., Ltd.: mixture of compounds represented by the following structures)

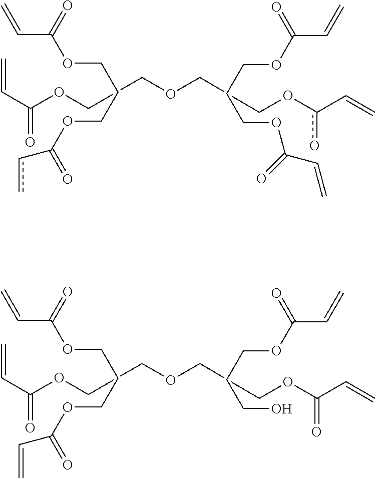

(M-5): (M-305: manufactured by TOAGOSEI CO., LTD.: mixture of compounds represented by the following structures)

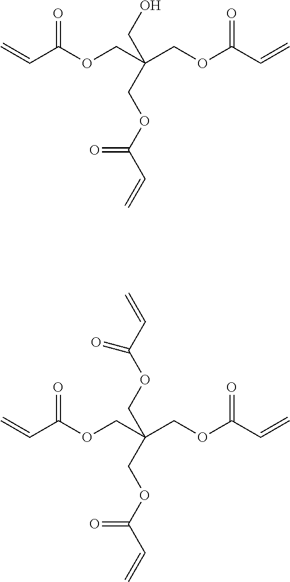

(M-6): (A-DPH: manufactured by SHIN-NAKAMURA CHEMICAL CO., LTD.: compound represented by the following structure)

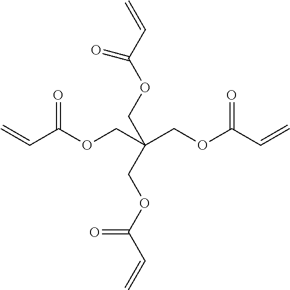 [SMILES: C=CC(=O)OCC(COC(=O)C=C)(COC(=O)C=C)COC(=O)C=C]

(M-7): (NK ESTER A-TMMT: manufactured by SHIN-NAKAMURA CHEMICAL CO., LTD.: compound represented by the following structure)

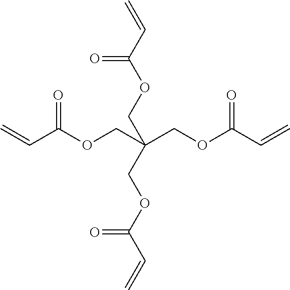 [SMILES: C=CC(=O)OCC(COC(=O)C=C)(COC(=O)C=C)COC(=O)C=C]

(M-8): (KAYARAD RP-1040: manufactured by Nippon Kayaku Co., Ltd.: compound represented by Formula (Z-6))

“Ratio obtained by dividing molecular weight by the number of polymerizable groups (molecular weight/number of polymerizable groups)” of compounds corresponding to the third polymerizable compound are shown below.

For “M-4” and “M-5” in Table 1, “ratio obtained by dividing molecular weight by the number of polymerizable groups (molecular weight/number of polymerizable groups)” of compounds corresponding to the third polymerizable compound in M-4 and M-5 are shown.

TABLE 1

| | Number of | Ratio of molecular |
|---|---|---|
| | polymerizable | weight/number of |
| Type | groups | polymerizable groups |
| M-4 | Hexafunctional | 0.0104 |
| M-5 | Tetrafunctional | 0.0114 |
| M-6 | Hexafunctional | 0.0104 |
| M-7 | Tetrafunctional | 0.0114 |
| M-8 | Tetrafunctional | 0.0076 |

<Synthesis of Alkali-Soluble Resin (b-1) (Epoxy Acrylate Resin (b-1) Having Carboxyl Group)>

A 500 mL four-neck flask was filled with a bisphenol fluorene-type epoxy resin (235 g) represented by the following Formula (a) (epoxy equivalent: 235), tetramethylammonium chloride (110 mg), 2,6-di-t-butyl-4-methylphenol (100 mg), acrylic acid (72.0 g), and propylene glycol monomethyl ether acetate (300 g), and in a state where air was being blown into the flask at a rate of 25 mL/min, these were dissolved by being heated at 90° C. to 100° C.

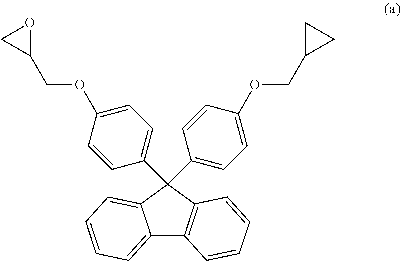 [SMILES: c1ccc2c(c1)-c1ccccc1C2(c1ccc(OCC2CC2)cc1)c1ccc(OCC2CO2)cc1]

Then, the turbid solution was slowly heated as it was, and heated up to 120° C. such that the components were thoroughly dissolved. Although the solution gradually became a transparent viscous solution, the solution was continuously stirred as it was. Meanwhile, the acid value thereof was measured, and until the acid value became 1.0 mg-KOH/g, the solution was continuously heated and stirred. It took 12 hours until the acid value became the intended value. Thereafter, the solution was cooled to room temperature, thereby obtaining bisphenol fluorene-type epoxy acrylate.

Subsequently, propylene glycol monomethyl ether acetate (300 g) was added to and dissolved in the obtained bisphenol fluorene-type epoxy acrylate (617.0 g) and then mixed with biphenyl-3,3′,4,4′-tetracarboxylic acid dianhydride (73.5 g) and tetraethylammonium bromide (1 g), and the mixture was slowly heated and reacted for 4 hours at 110° C. to 115° C.

After the disappearance of acid anhydride groups was confirmed, the solution was mixed with 1,2,3,6-tetrahydrophthalic acid anhydride (38.0 g) and allowed to react for 6 hours at 90° C., thereby obtaining an alkali-soluble resin (b-1) having an acid value of 100 mg-KOH/g and a molecular weight of 3,900 (weight-average molecular weight measured by gel permeation chromatography (GPC) and expressed in terms of polystyrene, the same is true for the following description).

<Synthesis of Alkali-Soluble Resin (b-2) (Carboxyl Group-Containing Epoxy (Meth)Acrylate Resin (b-2))>

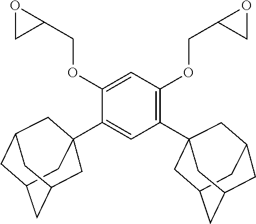 [SMILES: c1c(OCC2CO2)c(C23CC4CC(CC(C4)C2)C3)cc(C23CC4CC(CC(C4)C2)C3)c1OCC1CO1]

The epoxy compound having the above structure (epoxy equivalent: 264) (50 g), acrylic acid (13.65 g), methoxybutyl acetate (60.5 g), triphenylphosphine (0.936 g), and p-methoxyphenol (0.032 g) were put into a flask equipped with a thermometer, a stirrer, and a cooling pipe, and allowed to react at 90° C. with stirring until the acid value thereof became equal to or smaller than 5 mgKOH/g. The reaction was performed for 12 hours, and as a result, an epoxy acrylate solution was obtained.

The epoxy acrylate solution (25 parts by mass), trimethylolpropane (TMP) (0.76 parts by mass), biphenyl tetracarboxylic acid dianhydride (BPDA) (3.3 parts by mass), and tetrahydrophthalic acid anhydride (THPA) (3.5 parts by mass) were put into a flask equipped with a thermometer, a stirrer, and a cooling pipe, and allowed to react in a state where the mixture was being slowly heated to 105° C. with stirring. At a point in time when the resin solution became transparent, the solution was diluted with methoxybutyl acetate such that the solid contents thereof became 50% by mass, thereby obtaining an alkali-soluble resin (b-2) (carboxyl group-containing epoxy (meth)acrylate resin (b-2)) having an acid value of 131 mgKOH/g and a weight-average molecular weight (Mw) of 2,600 that was measured by GPC and expressed in terms of polystyrene.

<Synthesis of Alkali-Soluble Resin (b-3) (Carboxyl Group-Containing Epoxy (Meth)Acrylate Resin (b-3)>

“XD 1000” manufactured by Nippon Kayaku Co., Ltd. (polyglycidyl ether of dicyclopentadiene.phenol polymer, epoxy equivalent: 252) (300 parts by mass), methacrylic acid (87 parts by mass), p-methoxyphenol (0.2 parts by mass), triphenylphosphine (5 parts by mass), and propylene glycol monomethyl ether acetate (255 parts by mass) were put into a reaction container and stirred until the acid value thereof became 3.0 mgKOH/g at 100° C. Then, tetrahydrophthalic acid anhydride (145 parts by mass) was added to the reaction container, and the mixture was allowed to react for 4 hours at 120° C., thereby obtaining an alkali-soluble resin (b-3) (carboxyl group-containing epoxy (meth)acrylate resin (b-3)) having solid contents of 50% by mass, an acid value of 100 mgKOH/g and a weight-average molecular weight (Mw) of 2,600 that was measured by GPC and expressed in terms of polystyrene.

(b-4): benzyl methacrylate/methacrylic acid copolymer (copolymerization ratio=70/30, molecular weight: 30,000)

<Photopolymerization Initiator>

(I-1) α-aminoketone-based initiator: Irgacure-907 (trade name, manufactured by BASF JAPAN, LTD.)

(I-2) α-aminoketone-based initiator: Irgacure-369 (trade name, manufactured by BASF JAPAN, LTD.)

(I-3) OXE-03: Irgacure OXE01 (trade name, manufactured by BASF JAPAN, LTD.)

(I-4) OXE-04: Irgacure OXE02 (trade name, manufactured by BASF JAPAN, LTD.)

(I-5) compound having the following structure

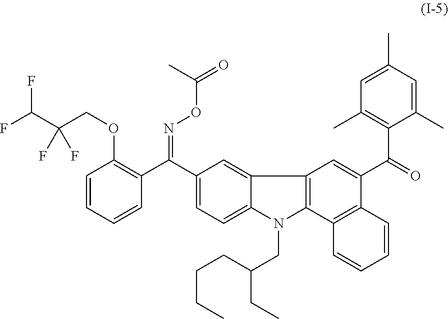 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

(I-6) compound represented by the following structure

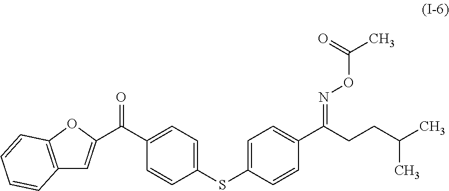 [SMILES: CC(=O)O/N=C(\CCC(C)C)c1ccc(Sc2ccc(C(=O)c3cc4ccccc4o3)cc2)cc1]

(I-7) DAROCUR TPO (trade name, manufactured by BASF JAPAN, LTD., compound having the following structure)

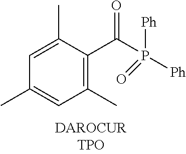 [SMILES: Cc1cc(C)c(C(=O)P(=O)(c2ccccc2)c2ccccc2)c(C)c1]

<Solvent>

(S-1) propylene glycol monomethyl ether acetate (PGMEA) (boiling point: 146° C.)

(S-2) cyclopentanone (boiling point: 131° C.)

(S-3) cyclohexanone (boiling point: 155° C.)

(S-4) cyclohexanol acetate (boiling point: 173° C.)

(S-5) propylene glycol dimethyl ether (boiling point: 175° C.)

(S-6) dipropylene glycol methyl ether acetate (boiling point: 213° C.)

(S-7) diethylene glycol monobutyl ether acetate (boiling point: 247° C.)

<Silane Coupling Agent>

AD-1: SH6040 (manufactured by Dow Corning Toray Co., Ltd.)

<Surfactant>

SF-1: F-475 (manufactured by DIC Corporation)

<Polymerization Inhibitor>

A-1: 4-methoxyphenol

<Preparation of Curable Composition>

Components were mixed together such that the amount (% by mass) of each of the components with respect to the total solid content became as shown in the composition described in Tables 2 to 4. Furthermore, various solvents were added thereto such that the concentration of solid contents became 15% by mass, and the mixture was stirred using a stirrer, thereby preparing a curable composition.

<Evaluation of Temporal Stability Against Delay>

By a spin coating method, an 8-inch silicon substrate was coated with the prepared curable composition such that the film thickness became 2.0 μm after exposure. The coating film was subjected to a heating treatment (pre-baking) for 120 seconds by using a hot plate with a temperature of 100° C., thereby obtaining a curable composition layer. Then, by using a defect inspection device ComPLUS (manufactured by Applied Materials, Inc.), the number of defects having a size equal to or greater than 0.5 μm on the surface of the curable composition layer were counted.

Thereafter, the formed curable composition layer was left to stand for 72 hours in an environment with a temperature of 23° C. and a humidity of 45%, and then by using the defect inspection device ComPLUS (manufactured by Applied Materials, Inc.), the number of defects having a size equal to or greater than 0.5 μm on the surface of the curable composition layer was counted again. A difference between the number of defects counted before the layer was left to stand and the number of defects counted after the layer was left to stand (number of defects after layer was left to stand—number of defects before layer was left to stand) was calculated. Based on the following standards, the defects were evaluated. Samples graded A or B were determined as being at the level that is unproblematic for practical use.

(Evaluation Standards)

A: Because the difference in the number of defects was equal to or smaller than 50, the sample was at the level unproblematic for practical use.

B: Because the difference in the number of defects was greater than 50 and equal to or smaller than 300, the sample was at the level unproblematic for practical use.

C: Because the difference in the number of defects was greater than 300, the sample was at the level problematic for practical use.

<Evaluation of Defects>

By a spin coating method, an 8-inch silicon substrate was coated with the prepared curable composition such that the film thickness became 2.0 μm after exposure. The coating film was subjected to a heating treatment (pre-baking) for 120 seconds by using a hot plate with a temperature of 100° C., thereby obtaining a curable composition layer. Then, by using a defect inspection device ComPLUS (manufactured by Applied Materials, Inc.), the number of defects having a size equal to or greater than 0.5 μm on the surface of the curable composition layer were counted. Based on the following standards, the defects were evaluated.

(Evaluation Standards)

A: Because the number of defects was equal to or smaller than 100, the sample was at the level unproblematic for practical use.

B: Because the number of defects was greater than 100 and equal to or smaller than 300, the sample was at the level unproblematic for practical use.

C: Because the number of defects was greater than 300, the sample was at the level problematic for practical use.

<Evaluation of in-Plane Uniformity>

By the same procedure as in <Evaluation of defect>, a curable composition layer was formed. Then, by using an i-line stepper exposure machine FPA-3000i5+ (manufactured by Canon Inc.), the entirety of the substrate was exposed in an exposure amount of 200 mJ/cm², thereby obtaining a cured film. By using a contact-type film thickness meter (Dektak), the film thickness of the cured film was measured at 56 spots, and the value of 3σ thereof was calculated.

Based on the following standards, in-plane uniformity was evaluated.

(Evaluation Standards)

A: 3σ was equal to or smaller than 0.1 μm.

B: 3σ was equal to or greater than 0.1 μm and less than 0.5 μm.

C: 3σ was equal to or greater than 0.5 μm.

<Preparation of Pattern-Like Cured Film>

By a spin coating method, an 8-inch silicon substrate, on which CT-4000L (manufactured by FUJIFILM Electronic Materials Co., Ltd.) was formed into a film having a thickness of 0.1 μm, was coated with the prepared curable composition such that the film thickness became 2.0 μm after exposure. Then, the coating film was subjected to a heating treatment (pre-baking) for 120 seconds by using a hot plate with a temperature of 100° C., thereby obtaining a curable composition layer.

Thereafter, by using an i-line stepper exposure machine FPA-3000i5+(manufactured by Canon Inc.), the curable composition layer was exposed through a predetermined mask in an exposure amount of 200 mJ/cm². For the exposed curable composition layer, puddle development was performed for 30 seconds at 23° C. by using a 0.3% aqueous solution of tetramethylammonium hydroxide. Subsequently, the curable composition layer was subjected to a rinsing treatment by spin shower and then further rinsed with pure water, thereby obtaining a pattern-like cured film having a linear pattern with a width of 100 μm.

<Evaluation of Residue>

The silicon substrate having the pattern-like cured film prepared in <Preparation of pattern-like cured film> was checked using a scanning electron microscope (SEM), and the film surface of the developed portion was observed.

Based on the following standards, residues were evaluated.

(Evaluation Standards)

A: No residue was observed in the substrate, and the cured film was at the level unproblematic for practical use.

B: Residues were observed at several sites in the substrate, but the cured film was at the level unproblematic for practical use.

C: Residues were observed in a portion of the substrate, but except for the portion of the substrate, the cured film was at the level unproblematic for practical use.

D: Residues were observed in the entirety of the substrate, and the cured film was at the level that is problematic.

E: The film remained in the developed portion, and the cured film was at the level that is unusable.

<Evaluation of Undercut>

The cross-section of the silicon substrate having the pattern-like cured film prepared in <Preparation of pattern-like cured film> was checked with SEM, and the width of eaves at the pattern edge was measured. Based on the following standards, undercut was evaluated.

(Evaluation Standards)

A: The undercut was equal to or smaller than 3 μm, and the cured film was at the level unproblematic for practical use.

B: The undercut was larger than 3 μm and equal to or smaller than 5 μm, and the cured film was at the level unproblematic for practical use.

C: The undercut was larger than 5 μm and equal to or smaller than 10 μm, and the cured film was at the level unproblematic for practical use.

D: The undercut was larger than 10 μm, and the cured film was at the level problematic for practical use.

<Evaluation of Post-Development Lenticulation>

For the pattern-like cured film prepared in <Preparation of pattern-like cured film>, a heating treatment (post-baking) was performed for 300 seconds by using a hot plate with a temperature of 200° C.

Then, by using an optical microscope MT-3600LW (manufactured by FLOVEL CO., LTD.), the appearance of the pattern edge of the cured film was checked, the line width of the pattern-like cured film was measured at 255 spots, and the value of 3a of the line width was calculated. Based on the following standards, post-development lenticulation was evaluated.

(Evaluation Standards)

A: No lenticulation was observed at the pattern edge, 3σ was equal to or smaller than 1 μm, and the cured film was at the level unproblematic for practical use.

B: Slight lenticulation was observed at the pattern edge, 3σ was equal to or smaller than 5 μm, and the cured film was at the level unproblematic for practical use.

C: Lenticulation was observed at the pattern edge or 3σ was greater than 5 μm, and the cured film was at the level problematic for practical use.

<Evaluation of Proportion of Residual Film>

By using a contact-type film thickness meter (Dektak), the film thickness of the exposed portion of the exposed curable composition layer not yet being developed in <Preparation of pattern-like cured film> and the film thickness of the cured film obtained after development were measured, and a rate of change in film thickness was calculated as shown in the following calculation formula. Based on the following standards, a proportion of residual film was evaluated.

Proportion of residual film (%)=(film thickness of cured film obtained after development)/(film thickness of exposed portion of curable composition layer not yet being developed)×100

(Evaluation Standards)

A: The proportion of residual film was equal to or higher than 80%, and the cured film was at the level unproblematic for practical use.

B: The proportion of residual film was equal to or higher than 70% and less than 80%, and the cured film was at the level unproblematic for practical use.

C: The proportion of residual film was lower than 70%.

In Tables 2 to 4, “Content (% by mass)” of each component represents the content (% by mass) of each component with respect to the total solid content of the curable composition.

In the column of “Carbon black, “(C-1)” or the like means that the carbon black dispersion composition (C-1) was used, and “Content (% by mass)” represents the content of carbon black.

In the column of “Alkali-soluble resin”, “Balance” means a fraction remaining after the total content (% by mass) of components (for example, carbon black, titanium black, a photopolymerizaiton initiator, a polymerizable compound, a silane coupling agent, a surfactant, a polymerization inhibitor, a carbon black dispersion composition, a dispersant in a titanium black dispersion composition, and the like) other than the alkali-soluble resin is subtracted from the total solid content (100% by mass) in each of the examples and the comparative examples.

TABLE 2

| | | Exam- | Exam- | Exam- | Exam- | Exam- | Exam- | Exam- | Exam- |
|---|---|---|---|---|---|---|---|---|---|
| | | ple 1 | ple 2 | ple 3 | ple 4 | ple 5 | ple 6 | ple 7 | ple 8 |
| Carbon black | Type | (c-1) | (c-1) | (c-1) | (c-1) | (c-1) | (c-1) | (c-1) | (c-1) |
| | Content (% by mass) | 30.53 | 30.53 | 30.53 | 30.53 | 30.53 | 30.53 | 30.53 | 30.53 |
| Titanium black | Type | — | — | — | — | — | — | — | — |
| | Content (% by mass) | — | — | — | — | — | — | — | — |
| Alkali-soluble resin | Type | (b-1) | (b-1) | (b-1) | (b-1) | (b-1) | (b-1) | (b-1) | (b-1) |
| | Content (% by mass) | Balance | Balance | Balance | Balance | Balance | Balance | Balance | Balance |
| Photopolymerization initiator | Type | (I-1) | (I-1) | (I-1) | (I-1) | (I-1) | (I-1) | (I-1) | (I-7) |
| | Content (% by mass) | 7.24 | 7.24 | 14.48 | 14.48 | 14.48 | 14.48 | 14.48 | 14.48 |
| | Type | (I-3) | (I-3) | — | — | — | — | — | — |
| | Content (% by mass) | 7.24 | 7.24 | — | — | — | — | — | — |
| Polymerizable compound | Type | (M-1) | (M-1) | (M-1) | (M-1) | (M-1) | (M-1) | (M-1) | (M-1) |
| | Content (% by mass) | 5.93 | 4.45 | 5.93 | 4.45 | 5.93 | 4.45 | 8.90 | 8.90 |
| | Type | (M-4) | (M-4) | (M-4) | (M-4) | (M-4) | (M-4) | (M-4) | (M-4) |
| | Content (% by mass) | 5.93 | 4.45 | 5.93 | 4.45 | 5.93 | 4.45 | 8.90 | 8.90 |
| | Type | (M-5) | (M-5) | (M-5) | (M-5) | (M-7) | (M-7) | — | — |
| | Content (% by mass) | 5.93 | 4.45 | 5.93 | 4.45 | 5.93 | 4.45 | — | — |
| | Type | — | (M-8) | — | (M-8) | — | (M-8) | — | — |
| | Content (% by mass) | — | 4.45 | — | 4.45 | — | 4.45 | — | — |
| Silane coupling agent | Type | — | — | — | — | — | — | — | — |
| | Content (% by mass) | — | — | — | — | — | — | — | — |
| Surfactant | Type | — | — | — | — | — | — | — | — |
| | Content (% by mass) | — | — | — | — | — | — | — | — |
| Polymerization inhibitor | Type | — | — | — | — | — | — | — | — |
| | Content (% by mass) | — | — | — | — | — | — | — | — |
| Solvent | | (S-5) | (S-5) | (S-5) | (S-5) | (S-5) | (S-5) | (S-5) | (S-5) |
| Evaluation of temporal stability against delay | | A | A | A | A | A | A | B | B |
| Evaluation of defects | | A | A | A | A | A | A | A | A |
| Evaluation of in-plane uniformity | | A | A | A | A | A | A | A | A |
| Evaluation of residues | | A | A | A | A | A | A | A | A |
| Evaluation of undercut | | A | A | A | A | A | A | A | B |
| Evaluation of post-development lenticulation | | A | A | A | A | A | A | B | B |
| Evaluation of proportion of residual film | | A | A | B | B | B | B | B | B |
| | | Exam- | Exam- | Exam- | Exam- | Exam- | Exam- | Exam- | Exam- |
| | | ple 9 | ple 10 | ple 11 | ple 12 | ple 13 | ple 14 | ple 15 | ple 16 |
| Carbon black | Type | (c-1) | (c-1) | (c-1) | (c-1) | (c-1) | (c-1) | (c-2) | (c-3) |
| | Content (% by mass) | 30.53 | 30.53 | 30.53 | 30.53 | 30.53 | 30.53 | 30.53 | 30.53 |
| Titanium black | Type | — | — | — | — | — | — | — | — |
| | Content (% by mass) | — | — | — | — | — | — | — | — |
| Alkali-soluble resin | Type | (b-1) | (b-1) | (b-1) | (b-1) | (b-1) | (b-1) | (b-1) | (b-1) |
| | Content (% by mass) | Balance | Balance | Balance | Balance | Balance | Balance | Balance | Balance |
| Photopolymerization initiator | Type | (I-3) | (I-4) | (I-5) | (I-6) | (I-1) | (I-1) | (I-1) | (I-1) |
| | Content (% by mass) | 14.48 | 14.48 | 14.48 | 14.48 | 14.48 | 14.48 | 14.48 | 14.48 |
| | Type | — | — | — | — | — | — | — | — |
| | Content (% by mass) | — | — | — | — | — | — | — | — |
| Polymerizable compound | Type | (M-1) | (M-1) | (M-1) | (M-1) | (M-2) | (M-3) | (M-3) | (M-3) |
| | Content (% by mass) | 8.90 | 8.90 | 8.90 | 8.90 | 8.90 | 8.90 | 8.90 | 8.90 |
| | Type | (M-4) | (M-4) | (M-4) | (M-4) | (M-4) | (M-4) | (M-4) | (M-4) |
| | Content (% by mass) | 8.90 | 8.90 | 8.90 | 8.90 | 8.90 | 8.90 | 8.90 | 8.90 |
| | Type | — | — | — | — | — | — | — | — |
| | Content (% by mass) | — | — | — | — | — | — | — | — |
| | Type | — | — | — | — | — | — | — | — |
| | Content (% by mass) | — | — | — | — | — | — | — | — |
| Silane coupling agent | Type | — | — | — | — | — | — | — | — |
| | Content (% by mass) | — | — | — | — | — | — | — | — |
| Surfactant | Type | — | — | — | — | — | — | — | — |
| | Content (% by mass) | — | — | — | — | — | — | — | — |
| Polymerization inhibitor | Type | — | — | — | — | — | — | — | — |
| | Content (% by mass) | — | — | — | — | — | — | — | — |

| | | | | | | | | |
|---|---|---|---|---|---|---|---|---|
| Solvent | (S-5) | (S-5) | (S-5) | (S-5) | (S-5) | (S-5) | (S-5) | (S-5) |
| Evaluation of temporal stability against delay | B | B | B | B | B | B | B | B |
| Evaluation of defects | A | A | A | A | A | A | A | A |
| Evaluation of in-plane uniformity | A | A | A | A | A | A | A | A |
| Evaluation of residues | A | A | A | A | B | B | A | A |
| Evaluation of undercut | A | A | A | A | A | A | A | A |
| Evaluation of post-development lenticulation | B | B | B | B | B | B | B | B |
| Evaluation of proportion of residual film | A | A | A | A | B | B | B | B |

TABLE 3

| | | Example 17 | Example 18 | Example 19 | Example 20 | Example 21 | Example 22 |
|---|---|---|---|---|---|---|---|
| Carbon black | Type | (C-1) | (C-1) | (C-1) | (C-1) | (C-1) | (C-1) |
| | Content (% by mass) | 30.53 | 30.53 | 30.53 | 30.53 | 30.53 | 30.53 |
| Titanium black | Type | — | — | — | — | — | — |
| | Content (% by mass) | — | — | — | — | — | — |
| Alkali-soluble resin | Type | (b-1) | (b-1) | (b-1) | (b-1) | (b-1) | (b-1) |
| | Content (% by mass) | Balance | Balance | Balance | Balance | Balance | Balance |
| Photopolymerization initiator | Type | (I-1) | (I-1) | (I-1) | (I-1) | (I-1) | (I-1) |
| | Content (% by mass) | 14.48 | 14.48 | 14.48 | 14.48 | 14.48 | 14.48 |
| | Type | — | — | — | — | — | — |
| | Content (% by mass) | — | — | — | — | — | — |
| Polymerizable compound | Type | (M-1) | (M-1) | (M-1) | (M-1) | (M-1) | (M-1) |
| | Content (% by mass) | 8.90 | 8.90 | 8.90 | 8.90 | 8.90 | 8.90 |
| | Type | (M-4) | (M-4) | (M-4) | (M-4) | (M-4) | (M-4) |
| | Content (% by mass) | 8.90 | 8.90 | 8.90 | 8.90 | 8.90 | 8.90 |
| Silane coupling agent | Type | — | — | — | — | — | — |
| | Content (% by mass) | — | — | — | — | — | — |
| Surfactant | Type | — | — | — | — | — | — |
| | Content (% by mass) | — | — | — | — | — | — |
| Polymerization inhibitor | Type | — | — | — | — | — | — |
| | Content (% by mass) | — | — | — | — | — | — |

| | | | | | | |
|---|---|---|---|---|---|---|
| Solvent | (S-1) | (S-2) | (S-3) | (S-4) | (S-6) | (S-7) |
| Evaluation of temporal stability against delay | B | B | B | B | B | B |
| Evaluation of defects | A | A | A | A | A | A |
| Evaluation of in-plane uniformity | C | C | B | A | A | A |
| Evaluation of residues | A | A | A | A | A | A |
| Evaluation of undercut | A | A | A | A | A | A |
| Evaluation of post-development lenticulation | B | B | B | B | B | B |
| Evaluation of proportion of residual film | B | B | B | B | B | B |

| | | Example 23 | Example 24 | Example 25 | Example 26 | Example 27 | Example 28 |
|---|---|---|---|---|---|---|---|
| Carbon black | Type | (C-1) | (C-1) | (C-1) | (C-1) | (C-1) | (C-1) |
| | Content (% by mass) | 30.53 | 30.53 | 30.53 | 30.53 | 30.53 | 30.53 |
| Titanium black | Type | — | — | — | — | — | — |
| | Content (% by mass) | — | — | — | — | — | — |
| Alkali-soluble resin | Type | (b-2) | (b-3) | (b-4) | (b-1) | (b-1) | (b-1) |
| | Content (% by mass) | Balance | Balance | Balance | Balance | Balance | Balance |
| Photopolymerization initiator | Type | (I-1) | (I-1) | (I-1) | (I-1) | (I-1) | (I-1) |
| | Content (% by mass) | 14.48 | 14.48 | 14.48 | 14.48 | 14.48 | 14.48 |
| | Type | — | — | — | — | — | — |
| | Content (% by mass) | — | — | — | — | — | — |
| Polymerizable compound | Type | (M-1) | (M-1) | (M-1) | (M-1) | (M-1) | (M-1) |
| | Content (% by mass) | 8.90 | 8.90 | 8.90 | 8.90 | 8.90 | 8.90 |
| | Type | (M-4) | (M-4) | (M-4) | (M-4) | (M-4) | (M-4) |
| | Content (% by mass) | 8.90 | 8.90 | 8.90 | 8.90 | 8.90 | 8.90 |
| Silane coupling agent | Type | — | — | — | (AP-1) | — | — |
| | Content (% by mass) | — | — | — | 1 | — | — |
| Surfactant | Type | — | — | — | — | (SF-1) | — |
| | Content (% by mass) | — | — | — | — | 0.21 | — |
| Polymerization inhibitor | Type | — | — | — | — | — | — |
| | Content (% by mass) | — | — | — | — | — | 0.001 |

| | | | | | | |
|---|---|---|---|---|---|---|
| Solvent | (S-5) | (S-5) | (S-5) | (S-5) | (S-5) | (S-5) |
| Evaluation of temporal stability against delay | B | B | B | B | B | B |
| Evaluation of defects | A | A | A | A | A | A |
| Evaluation of in-plane uniformity | A | A | A | A | A | A |
| Evaluation of residues | A | A | A | A | A | A |
| Evaluation of undercut | A | A | A | A | A | A |
| Evaluation of post-development lenticulation | B | B | B | B | B | B |
| Evaluation of proportion of residual film | B | B | B | B | B | B |

TABLE 4

| | | Example 29 | Example 30 | Example 31 | Example 32 | Example 33 | Example 34 |
|---|---|---|---|---|---|---|---|
| Carbon black | Type | (C-1) | (C-1) | (C-1) | (C-1) | (C-1) | (C-1) |
| | Content (% by mass) | 30.53 | 30.53 | 30.53 | 30.53 | 30.53 | 30.53 |
| Titanium black | Type | — | — | — | — | — | — |
| | Content (% by mass) | — | — | — | — | — | — |
| Alkali-soluble resin | Type | (b-1) | (b-1) | (b-1) | (b-1) | (b-1) | (b-1) |
| | Content (% by mass) | Balance | Balance | Balance | Balance | Balance | Balance |
| Photopolymerization initiator | Type | (I-1) | (I-1) | (I-1) | (I-1) | (I-1) | (I-1) |
| | Content (% by mass) | 14.48 | 14.48 | 7.24 | 7.24 | 7.24 | 7.24 |
| | Type | — | — | (I-3) | (I-3) | (I-3) | (I-3) |
| | Content (% by mass) | — | — | 7.24 | 7.24 | 7.24 | 7.24 |
| Polymerizable compound | Type | (M-1) | (M-1) | (M-1) | (M-1) | (M-1) | (M-1) |
| | Content (% by mass) | 8.90 | 8.90 | 5.93 | 5.93 | 5.93 | 5.93 |
| | Type | (M-4) | (M-4) | (M-4) | (M-4) | (M-4) | (M-4) |
| | Content (% by mass) | 8.90 | 8.90 | 5.93 | 5.93 | 5.93 | 5.93 |
| | Type | — | — | (M-5) | (M-5) | (M-5) | (M-5) |
| | Content (% by mass) | — | — | 5.93 | 5.93 | 5.93 | 5.93 |
| Silane coupling agent | Type | (AD-1) | (AD-1) | (AD-1) | — | — | (AD-1) |
| | Content (% by mass) | 1 | 1 | 1 | — | — | 1 |
| Surfactant | Type | (SF-1) | (SF-1) | — | (SF-1) | — | (SF-1) |
| | Content (% by mass) | 0.21 | 0.21 | — | 0.21 | — | 0.21 |
| Polymerization inhibitor | Type | (A-1) | (A-1) | — | — | (A-1) | (A-1) |
| | Content (% by mass) | 0.001 | 0.001 | — | — | 0.001 | 0.001 |

| | | | | | | |
|---|---|---|---|---|---|---|
| Solvent | (S-5) | (S-5) | (S-5) | (S-5) | (S-5) | (S-5) |
| Evaluation of temporal stability against delay | B | B | A | A | A | A |
| Evaluation of defects | A | A | A | A | A | A |
| Evaluation of in-plane uniformity | A | A | A | A | A | A |
| Evaluation of residues | A | A | A | A | A | A |
| Evaluation of undercut | A | A | A | A | A | A |
| Evaluation of post-development lenticulation | B | B | A | A | A | A |
| Evaluation of proportion of residual film | B | B | A | A | A | A |

| | | | | Comparative | Comparative | Comparative |
|---|---|---|---|---|---|---|
| | | Example 35 | Example 36 | Example 1 | Example 2 | Example 3 |
| Carbon black | Type | (C-1) | (C-1) | (C-1) | (C-1) | (C-1) |
| | Content (% by mass) | 15.265 | 15.265 | 30.53 | 30.53 | 30.53 |
| Titanium black | Type | (T-1) | (T-1) | — | — | — |
| | Content (% by mass) | 15.265 | 15.265 | — | — | — |
| Alkali-soluble resin | Type | (b-1) | (b-1) | (b-1) | (b-1) | (b-1) |
| | Content (% by mass) | Balance | Balance | Balance | Balance | Balance |
| Photopolymerization initiator | Type | (I-1) | (I-1) | (I-1) | (I-1) | (I-1) |
| | Content (% by mass) | 14.48 | 7.24 | 14.48 | 14.48 | 14.48 |
| | Type | — | (I-3) | — | — | — |
| | Content (% by mass) | — | 7.24 | — | — | — |
| Polymerizable compound | Type | (M-1) | (M-1) | (M-1) | (M-4) | (M-1) |
| | Content (% by mass) | 8.90 | 5.93 | 17.79 | 17.79 | 8.90 |
| | Type | (M-4) | (M-4) | — | — | (M-6) |
| | Content (% by mass) | 8.90 | 5.93 | — | — | 8.90 |
| | Type | — | (M-5) | — | — | — |
| | Content (% by mass) | — | 5.93 | — | — | — |
| Silane coupling agent | Type | — | — | — | — | — |
| | Content (% by mass) | — | — | — | — | — |
| Surfactant | Type | — | — | — | — | — |
| | Content (% by mass) | — | — | — | — | — |
| Polymerization inhibitor | Type | — | — | — | — | — |
| | Content (% by mass) | — | — | — | — | — |

| | | | | | |
|---|---|---|---|---|---|
| Solvent | (S-5) | (S-5) | (S-5) | (S-5) | (S-5) |
| Evaluation of temporal stability against delay | B | A | C | C | C |
| Evaluation of defects | A | A | B | B | A |
| Evaluation of in-plane uniformity | A | A | A | A | A |
| Evaluation of residues | A | A | C | A | C |
| Evaluation of undercut | A | A | A | A | A |
| Evaluation of post-development lenticulation | A | A | A | A | B |
| Evaluation of proportion of residual film | A | A | B | B | B |

As shown in Tables 2 to 4, it was confirmed that in a case where the curable composition according to the embodiment of the present invention is used, the desired effects are obtained.

By comparing Example 1 with Example 7, it was confirmed that in a case where the curable composition contains at least 4 or more kinds of compounds as a curable compound (or in a case where the curable composition contains at least 3 or more kinds of compounds having different numbers of polymerizable groups as a polymerizable compound), the evaluation result of the temporal stability against delay and the evaluation result of the post-development lenticulation are further improved.

By comparing Examples 3 to 6 with other examples, it was confirmed that an aspect is preferable in which the curable composition contains the compound represented by Formula (Z-1), the compound represented by Formula (Z-5) (preferably the compound represented by Formula (Z-5-1)), the compound represented by Formula (Z-6) (preferably the compound represented by Formula (Z-6-1)), and the compound represented by Formula (Z-7) (preferably the compound represented by Formula (Z-7-1)).

By comparing Example 1 with Example 3, it was confirmed that in a case where an oxime ester-based polymerization initiator is used, the evaluation result of the proportion of residual film is further improved.

By comparing Example 7 with Example 8, it was confirmed that in a case where an α-aminoketone-based polymerization initiator is used, the evaluation result of the undercut is further improved.

By comparing Example 7 with Examples 13 and 14, it was confirmed that in a case where the first polymerizable compound is the compound represented by Formula (Z-1), and at least two R's among six R's are a group represented by Formula (Z-2) and the others are a group represented by Formula (Z-3), the evaluation result of residues is further improved.

By comparing Example 7 with Examples 17 to 21, it was confirmed that in a case where a solvent having a boiling point equal to or higher than 170° C. is used, the evaluation result of the in-plane uniformity is further improved.

By comparing Example 7 with Example 35, it was confirmed that in a case where titanium black is used, the evaluation result of the post-development lenticulation and the evaluation result of the proportion of residual film are further improved.

<Preparation and Evaluation of Light Blocking Film for Wafer-Level Lens>

A lens film was formed by the following operation.

[1. Formation of Resin Film]

A 5×5 cm glass substrate (thickness: 1 mm, manufactured by Schott AG, BK7) was coated with a curable composition for lens (composition obtained by adding 1% by mass of aryl sulfonium salt derivative (SP-172 manufactured by ADEKA CORPORATION) (2 mL) to alicyclic epoxy resin (EHPE-3150 manufactured by Daicel Chemicals Industries Ltd.)), and the coating film was cured by being heated for 1 minute at 200° C., thereby forming a resin film on the glass substrate.

In order for the film thickness of the curable composition layer to be 2.0 μm, a rotation speed of a spin coater was adjusted, the glass substrate on which the resin film was formed was uniformly coated with the curable composition of each of the examples, and the coating film was subjected to a heating treatment for 120 seconds by using a hot plate with a surface temperature of 120° C.

Then, by using a high-pressure mercury lamp, the obtained curable composition layer was exposed through a photomask having a 10 mm hole pattern in an exposure amount of 500 mJ/cm².

For the exposed curable composition layer, by using a 0.3% by mass aqueous solution of tetramethylammonium hydroxide, puddle development was performed for 60 seconds at a temperature of 23° C. Subsequently, the glass substrate was rinsed by spin shower and further rinsed with pure water, thereby obtaining a pattern-like cured film on the peripheral portion of the glass substrate.

By using a curable composition for lens (composition obtained by adding 1% by mass of aryl sulfonium salt derivative (SP-172 manufactured by ADEKA CORPORATION) to alicyclic epoxy resin (EHPE-3150 manufactured by Daicel Chemicals Industries Ltd.)), a curable resin layer was formed on the glass substrate on which the pattern-like cured film was formed. By using a quartz mold having a lens shape, the shape was transferred to the curable composition layer, and the curable composition layer was cured in an exposure amount of 400 mJ/cm² by using a high-pressure mercury lamp, thereby preparing a wafer-level lens array having a plurality of wafer-level lenses.

The prepared wafer-level lens array was cut, a lens module was prepared in the lens array, and the lens module was mounted on a solid-state imaging element and a sensor substrate, thereby preparing a solid-state imaging device. The obtained wafer-level lens had no residues on the aperture of the lens, had excellent transparency, exhibited high uniformity of the coating surface of the portion of the cured film, and had high light blocking properties.

### EXPLANATION OF REFERENCES

100: solid-state imaging device
101: solid-state imaging element
102: imaging portion
103: cover glass
104: spacer
105: laminated substrate
106: chip substrate
107: circuit substrate
108: electrode pad
109: external connection terminal
110: penetration electrode
111: lens layer
112: lens material
113: support
114, 115: light blocking film
201: light-receiving element
202: color filter
203: microlens
204: substrate
205b: blue pixel
205r: red pixel
205g: green pixel
205bm: black matrix
206: p-well layer
207: reading gate portion
208: vertical electric charge transfer path
209: element separation region
210: gate insulating film
211: vertical electric charge transfer electrode
212: light blocking film
213, 214: insulating film
215: planarization film

What is claimed is:

1. A curable composition comprising:
carbon black; and
a polymerizable compound,
wherein the polymerizable compound contains a first polymerizable compound having a ring-opened structure of 6-caprolactone and a second polymerizable compound having a hydroxyl group.

2. The curable composition according to claim 1,
wherein the polymerizable compound further contains a third polymerizable compound which is a compound different from the first polymerizable compound and the second polymerizable compound and has a plurality of polymerizable groups.

3. The curable composition according to claim 2,
wherein the third polymerizable compound contains a polymerizable compound which is a compound different from the first polymerizable compound and the second polymerizable compound and has a plurality of polymerizable groups, and
a ratio obtained by dividing the number of the polymerizable groups by a molecular weight of the polymerizable compound contained in the third polymerizable compound is equal to or higher than 0.0100 and less than 0.0120.

4. The curable composition according to claim 1,
wherein at least 4 or more kinds of compounds are contained as the polymerizable compound.

5. The curable composition according to claim 1,
wherein at least 3 or more kinds of compounds having different numbers of polymerizable groups are contained as the polymerizable compound.

6. The curable composition according to claim 1,
wherein at least 4 or more kinds of compounds having different numbers of polymerizable groups are contained as the polymerizable compound.

7. The curable composition according to claim 1,
wherein the first polymerizable compound is a compound represented by Formula (Z-1), 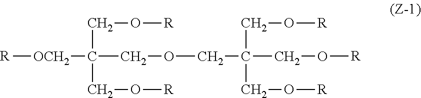
in Formula (Z-1), all of six R's are a group represented by Formula (Z-2), or one to five R's among six R's are a group represented by Formula (Z-2) and the others are a group represented by Formula (Z-3), 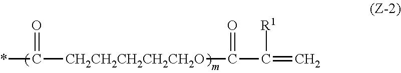
in Formula (Z-2), R¹ represents a hydrogen atom or a methyl group, m represents 1 or 2, and * represents a binding position, 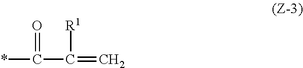
in Formula (Z-3), R¹ represents a hydrogen atom or a methyl group, and * represents a binding position.

8. The curable composition according to claim 7,
wherein two R's among six R's are a group represented by Formula (Z-2), and the others are a group represented by Formula (Z-3).

9. The curable composition according to claim 1,
wherein the second polymerizable compound is selected from the group consisting of a compound represented by Formula (Z-4) and a compound represented by Formula (Z-5), 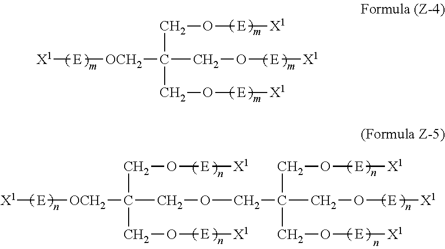
in Formula (Z-4), E each independently represents —((CH₂)_{y}CH₂O)-*1 or —((CH₂)_{y}CH(CH₃)O)-*1, y each independently represents an integer of 0 to 10, m each independently represents an integer of 0 to 10, one to three X¹'s among four X¹'s represent a (meth)acryloyl group and the others represent a hydrogen atom, and *1 represents a binding position on the X¹ side,
in Formula (Z-5), E each independently represents —((CH₂)_{y}CH₂O)-*1 or —((CH₂)_{y}CH(CH₃)O)-*1, y each independently represents an integer of 0 to 10, n each independently represents an integer of 0 to 10, one to five X¹'s among six X¹'s represent a (meth)acryloyl group and the others represent a hydrogen atom, and *1 represents a binding position on the X¹ side.

10. The curable composition according to claim 1,
wherein the polymerizable compound contains a compound represented by Formula (Z-1), a compound represented by Formula (Z-5), a compound represented by Formula (Z-6), and a compound represented by Formula (Z-7), 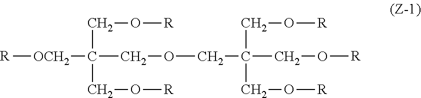
in Formula (Z-1), all of six R's are a group represented by Formula (Z-2), or one to five R's among six R's are a group represented by Formula (Z-2) and the others are a group represented by Formula (Z-3), 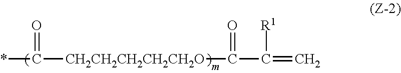
in Formula (Z-2), R¹ represents a hydrogen atom or a methyl group, m represents 1 or 2, and * represents a binding position, 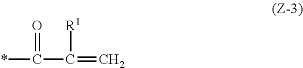
in Formula (Z-3), R¹ represents a hydrogen atom or a methyl group, and * represents a binding position, 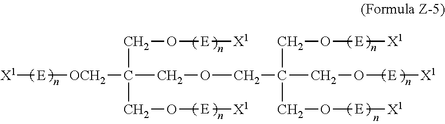
in Formula (Z-5), E each independently represents —((CH₂)_{y}CH₂O)-*1 or —((CH₂)_{y}CH(CH₃)O)-*1, y each independently represents an integer of 0 to 10, n each independently represents an integer of 0 to 10, one to five X¹'s among six X¹'s represent a (meth)acryloyl group and the others represent a hydrogen atom, and *1 represents a binding position on the X¹ side, 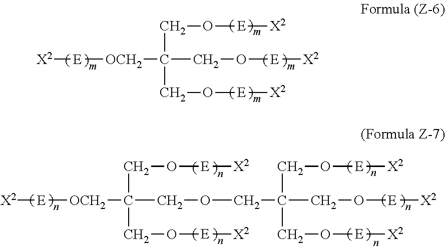
in Formula (Z-6), E each independently represents —((CH₂)_{y}CH₂O)-*2 or —((CH₂)_{y}CH(CH₃)O)-*2, y each independently represents an integer of 0 to 10, m each independently represents an integer of 0 to 10, X² represents a (meth)acryloyl group, and *2 represents a binding position on the X² side,
in Formula (Z-7), E each independently represents —((CH₂)_{y}CH₂O)-*2 or —((CH₂)_{y}CH(CH₃)O)-*2, y each independently represents an integer of 0 to 10, n each independently represents an integer of 0 to 10, X² represents a (meth)acryloyl group, and *2 represents a binding position on the X² side.

11. The curable composition according to claim 1, further comprising:
an α-aminoketone-based polymerization initiator.

12. The curable composition according to claim 1, further comprising:
an oxime ester-based polymerization initiator.

13. The curable composition according to claim 1, further comprising:
an alkali-soluble resin which has a curable group and a cardo structure.

14. The curable composition according to claim 1, further comprising:
a solvent having a boiling point equal to or higher than 170° C.

15. The curable composition according to claim 1, further comprising:
titanium black.

16. A cured film obtained by curing the curable composition according to claim 1.

17. A solid-state imaging device comprising:
the cured film according to claim 16.

18. A manufacturing method of a cured film, comprising:
a step of forming a curable composition layer by using the curable composition according to claim 1;
a step of exposing the curable composition layer; and
a step of developing the exposed curable composition layer by using a developer.

19. The curable composition according to claim 2,
wherein at least 4 or more kinds of compounds are contained as the polymerizable compound.

20. The curable composition according to claim 2,
wherein at least 3 or more kinds of compounds having different numbers of polymerizable groups are contained as the polymerizable compound.
